(19) United States
(12) Patent Application Publication
(10) Pub. No.: US 2025/0054680 A1
(43) Pub. Date: Feb. 13, 2025

(54) HIGH-INTEGRATION-LEVEL CARRIER PLATE AND POWER SUPPLY MODULE

(71) Applicant: SHANGHAI METAPWR ELECTRONICS CO., LTD, Shanghai (CN)

(72) Inventors: Shouyu Hong, Shanghai (CN); Jianhong ZENG, Shanghai (CN)

(73) Assignee: SHANGHAI METAPWR ELECTRONICS CO., LTD, Shanghai (CN)

(21) Appl. No.: 18/796,318

(22) Filed: Aug. 7, 2024

(30) Foreign Application Priority Data
Aug. 8, 2023 (CN) 202310988470.2

(51) Int. Cl. H01F 27/28; H01F 27/24; H05K 1/11; H05K 7/20

(52) U.S. Cl. CPC H01F 27/28; H01F 27/24; H05K 1/115; H05K 7/209; H05K 2201/1003

(57) ABSTRACT

A high-integration-level carrier plate includes at least two prefabricated printed circuit board lamination layers, at least one hollowed-out area is formed in the printed circuit board lamination layer, the hollowed-out areas are embedded in the carrier plate, the printed circuit board lamination layers are fixedly connected through an insulating bonding dielectric layer and are electrically connected through at least one bonding material piece, and at least one power supply circuit assembly is arranged in the hollowed-out area; the printed circuit board lamination layer comprises at least a part of windings, and the windings and the magnetic cores are used for forming magnetic elements in the power supply circuit assembly through mutual cooperation.

### CROSS-REFERENCE TO RELATED APPLICATION

This application claims the priority benefit of China patent application serial no. 202310988470.2 filed on Aug. 8, 2023. The entirety of the above-mentioned patent application is hereby incorporated by reference herein and made a part of this specification.

### BACKGROUND

### Technical Field

The present application belongs to the field of high-frequency power supplies, and particularly relates to a high-integration carrier plate and power supply module.

### Description of Related Art

Along with increasingly vigorous requirements of various artificial intelligence, data processing and the like, global computing power energy consumption presents explosive growth. Moreover, due to the fact that the size limitation of the computing power units is extremely high, higher and higher requirements are provided for the occupied area, the height, the efficiency, the heat dissipation and the like of the energy processing unit.

A typical two-stage power supply architecture has a front stage of 48V to 12V (5V) and a back stage of 12V (5V) to the working voltage of the processor, and is near to 1V. The front-stage module usually comprises a magnetic element and a transformer due to high voltage conversion, and the rear stage usually adopts a Buck circuit and comprises a magnetic element and an inductor.

The method comprises the following steps: firstly, forming a first lamination layer comprising a part of a winding; arranging a magnetic core in the hole groove structure in a manner that a hole groove and other structures are formed in the first lamination layer in a similar copper burying process; then, stacking layers above the first lamination layer one by one to form a carrier plate with an embedded magnetic core structure; and enabling each turn of the winding to be electrically connected to the surface of the carrier plate through a through hole penetrating through the whole carrier plate, further wiring through a carrier plate, and further wiring through a blind hole in the process of laminating through a through hole and a blind hole in the first lamination layer, as shown in FIG. 1A. The method has the following technical problems:

One side edge is connected with each winding through a through hole, the mutual interference between the layers enables the integrity of the winding to be damaged, and the impedance is increased

The side edges are vertically interconnected by using via holes, and the occupied space area is large

Three magnetic cores are connected layer by layer through blind holes, so that the cost is increased

The magnetic core is directly embedded in the substrate, the matching problem of the magnetic core material and the substrate exists, the magnetic core loss can be increased for a specific material, and the structural reliability risk is increased.

As shown in FIG. 1B, a redundant area is reserved in the hollowed-out part in the process of embedding the magnetic core, so that the matching problem of the magnetic core and the carrier plate can be solved.

However, on one hand, the method cannot solve the other three-point technical problems, but also brings a new technical problem:

In order to ensure that subsequent lamination can be realized, the thickness of the first basic material dielectric layer above the first lamination layer is larger, for example, more than 0.2 mm, so that height space waste is caused.

On the other hand, when the thickness of the first lamination layer is large, if the blind hole is adopted for connection, in order to meet the requirement of the electroplating width-to-depth ratio, the hole size of the blind hole is increased accordingly; moreover, the problem of side wall liquid leakage during blind hole electroplating needs to be considered, enough safe distance needs to be reserved, and space is further wasted. Moreover, when a traditional cavity is lamination one by one, when the support is insufficient, the problems of poor interlayer filling, low compactness and the like are prone to occurring, so that a lot of reliability risks are generated.

Therefore, how to realize the integration of the magnetic element and the integration of the magnetic element and the power device in a high space utilization rate and a high reliability mode is an urgent problem to be solved.

### SUMMARY

The application aims to provide a high-integration-level carrier plate and a power supply module, the carrier plate can embed the magnetic structure, the thickness of the bonding dielectric layer can be far smaller than the thickness of the lamination layer, the winding vertical section can be formed through the side wall metal piece and the outer side metal piece, the height of the power supply module is greatly reduced, heat dissipation is facilitated, and meanwhile the wiring flexibility is improved.

The application discloses a carrier plate with high integration level. The carrier plate comprises at least two prefabricated printed circuit board lamination layers, the at least one printed circuit board lamination layer is provided with a first surface, at least one hollowed-out area is formed in the first surface, the hollowed-out area is embedded in the carrier plate, the printed circuit board lamination layer is fixedly connected through an insulating bonding dielectric layer, an electrical connector penetrating through the bonding dielectric layer is arranged in the carrier plate, and at least one power supply circuit assembly is arranged in the hollowed-out area.

Preferably, the power supply circuit assembly comprises at least one magnetic core, the printed circuit board lamination layer comprises at least one part of windings, and the winding and the magnetic core are used for forming magnetic elements in the power supply circuit assembly through mutual cooperation.

Preferably, at least one hollow area is provided with a side wall metal piece, the at least one side wall metal piece is used for forming at least a part of windings, and the winding and the magnetic core are used for forming magnetic elements in the power supply circuit assembly through mutual cooperation.

Preferably, an outer side metal part is arranged on the side wall of the outer edge of the printed circuit board lamination layer where the side wall metal piece is located, and the outer side metal part is used for forming the at least one part of windings.

Preferably, the electrical connector penetrating through the bonding dielectric layer comprises a bonding material piece, and the bonding material piece is made of a non-remelting conductive bonding material; and the non-remelting conductive bonding material does not remelting in 220° C.

Preferably, the power supply circuit assembly and the printed circuit board lamination layer are electrically connected through one or more conductive connecting pieces, and the conductive connecting piece is made of a non-remelting conductive bonding material; and the non-remelting conductive bonding material does not remelting in 220° C.

Preferably, the non-remelting conductive bonding material comprises at least one of brazing filler metal, tin-silver alloy, tin-copper alloy, tin-silver-copper alloy, tin-antimony alloy, gold-tin alloy, high-lead solder, silver sintering slurry, copper sintering slurry, instantaneous liquid-phase sintering material or conductive slurry.

Preferably, the electrical connector penetrating through the bonding dielectric layer comprises a via hole electroplating piece.

Preferably, the material of the bonding dielectric layer comprises at least one of a prepreg or ABF.

Preferably, wherein an insulating filler is provided in the hollow area, and the insulating filler covers the power supply circuit assembly.

Preferably, the hollow structure comprises at least one step area, and power supply circuit assemblies with different heights are arranged in the step area and the step area respectively.

Preferably, at least one printed circuit board lamination layer is provided with a second surface, the second surface is not provided with a hollowed-out area, a power supply circuit assembly is arranged on the second surface, and the power supply circuit assembly on the second surface is located in a hollowed-out area formed in the other printed circuit board lamination layer.

Preferably, at least two adjacent printed circuit board lamination layers are provided with hollowed-out areas, and the corresponding hollowed-out areas are communicated.

Preferably, at least three printed circuit board lamination layers are arranged; and at least one printed circuit board lamination layer is penetrated by a hollowed-out area.

Preferably, at least three printed circuit board lamination layers are arranged; at least two hollowed-out areas are arranged; and the hollowed-out areas are respectively arranged on different printed circuit board lamination layers and/or on different surfaces of the printed circuit board lamination layer.

Preferably, wherein the magnetic core spans at least one printed circuit board lamination layer, the plurality of hollow areas are provided, and the plurality of hollow areas are respectively used for accommodating a part of the magnetic core.

Preferably, at least one power supply circuit assembly is electrically connected with two different printed circuit board lamination layers through pins.

Preferably, the printed circuit board lamination layer corresponding to the at least one pin is provided with an electrical connection semi-counterbore. Preferably, at least one of the pins is an elastic pin.

Preferably, at least one hollow area is provided with a side wall metal piece, and the at least one side wall metal piece is used for forming a signal shielding layer.

Preferably, a plurality of side wall metal pieces are arranged on one side wall of the same hollow area, and the side wall metal pieces extend in the thickness direction of the carrier plate and are arranged in an array in the horizontal direction.

Preferably, the side wall metal member is provided with solder at the top or bottom of the hollow region, or the side wall metal member and the printed circuit board lamination layer are electrically connected by means of a flying wire.

A high-integration transformer unit comprises an annular magnetic core, a primary winding, a secondary winding and a carrier plate, wherein the carrier comprises at least two prefabricated printed circuit board lamination layers; an annular hollow area used for accommodating the annular magnetic core is formed in the at least one printed circuit board lamination layer, the printed circuit board lamination layer wraps the annular magnetic core through buckling, and the printed circuit board lamination layer is fixedly connected through a bonding dielectric layer; and at least one part of the primary side winding and the secondary side winding is arranged in the printed circuit board lamination layer.

Preferably, one of the primary winding or the secondary winding is arranged on the surface of the annular magnetic core, and the lamination layer of the primary winding or the secondary winding is electrically connected with the printed circuit board lamination layer through at least two conductive connecting pieces.

Preferably, an insulating transition layer is further arranged between one of the primary winding or the secondary winding and the surface of the annular magnetic core.

Preferably, an insulation protection layer is further arranged on the outer side of one of the primary winding or the secondary winding.

Preferably, wherein the other one of the primary winding or the secondary winding is arranged on the printed circuit board lamination layer and comprises a first winding and a second winding which are nested inside and outside.

Preferably, a plurality of side wall metal pieces are arranged in the annular hollowed-out area, the side wall metal pieces extend in the thickness direction of the carrier plate and are arranged in an array in the horizontal direction, and the side wall metal pieces are used for forming vertical parts of the first winding.

Preferably, a plurality of outer side metal pieces are arranged on the side wall of the outer edge of the printed circuit board lamination layer, and the outer side metal pieces are used for forming vertical parts of the second winding.

Preferably, wherein the at least two conductive connectors are respectively electrically connected to different printed circuit board lamination layers.

Preferably, wherein the primary winding and/or the secondary winding comprise at least three windings nested inside and outside.

Preferably, a vertical via hole is formed in the carrier plate, a bonding material piece is arranged at the position, corresponding to the vertical via hole, of the bonding dielectric layer, and the vertical via hole and the bonding material piece are used for forming a vertical section of the primary winding and/or a vertical section of the secondary winding.

Preferably, wherein a vertical via hole is provided in the carrier plate, the vertical via hole penetrates the bonding dielectric layer, and the vertical via hole is used for forming a vertical section of the primary winding and/or a vertical section of the secondary winding.

Preferably, at least one vertical via hole arranged in the middle of the annular magnetic core is a vertical section shared by a plurality of primary windings or a vertical section shared by a plurality of secondary windings.

Preferably, the transformer further comprises a circuit element, wherein the circuit element comprises a switching element and/or a driving element and/or a capacitive element and/or a controller; and the switching element comprises a primary side switching element and/or a secondary side switching element, the primary side winding switching element and the primary side winding are connected in series, and the secondary side winding switching element and the secondary side winding are connected in series.

Preferably, the carrier plate is provided with a heat dissipation surface; the circuit element is arranged on the heat dissipation surface, and/or the circuit element is arranged in the hollow area and is arranged on one surface close to the heat dissipation surface.

Preferably, the switch elements are arranged on two opposite surfaces of the printed circuit board lamination layer in parallel and correspond to each other in position, one of the switch elements arranged in parallel is located in the hollow area, and the other one of the switch elements is located on the outer surface of the carrier plate.

Preferably, the transformer unit further comprises a plastic package body, the circuit element is arranged on the outer surface of the carrier plate, and the plastic package body wraps the circuit element and the outer surface.

Preferably, a conductive adapter is arranged in the plastic package body, one end of the conductive adapter is electrically connected with the carrier plate, and the other end of the conductive adapter is exposed out of the surface of the plastic package body; and the conductive adapter is arranged at the position adjacent to the central axis of the transformer unit.

The application discloses a power supply device with a high-integration level two-stage architecture. The power supply device comprises a two-stage architecture carrier plate, a front-stage magnetic core, a front-stage winding, a front-stage circuit element and a rear-stage circuit element, wherein the two-stage architecture carrier plate comprises at least two printed circuit board lamination layers, the two-stage architecture carrier plate is divided into a front-stage element area and a rear-stage element area according to circuit functions, and the front-stage element area is an annular area surrounding the rear-stage element area;
at least one printed circuit board lamination layer is provided with an annular hollowed-out area in the front-stage element area, the front-stage magnetic core is annular, and the front-stage magnetic core is arranged in the annular hollowed-out area;
the front-stage winding is arranged in the front-stage element area, and at least one part of the front-stage winding is arranged in the printed circuit board lamination layer;
the at least one printed circuit board lamination layer is provided with a middle hollowed-out area in the rear-stage element area, and at least one part of the rear-stage circuit element is arranged in the middle hollowed-out area;
the printed circuit board lamination layer is fixedly connected by means of a bonding dielectric layer, and an electrical connector penetrating through the bonding dielectric layer is provided in the two-stage architecture carrier.

Preferably, the area of the front-stage element area is smaller than that of the rear-stage element area.

Preferably, at least a part of the front-stage circuit element is arranged on the outer surface of the two-stage architecture carrier plate, and/or at least a part of the post-stage circuit element is arranged on the outer surface of the two-stage architecture carrier plate.

Preferably, the two-stage architecture carrier plate has a first surface; in the front-stage element area or the rear-stage element area of the first surface, the printed circuit board lamination layer at the outermost layer is hollowed out, so that the printed circuit board lamination layer of the secondary outer layer is exposed; and at least a part of the front-stage circuit element and at least a part of the rear-stage circuit element are arranged in a staggered mode on the first surface.

Preferably, wherein the rear-stage circuit element comprises a rear-stage magnetic core, and the rear-stage magnetic core is arranged in the middle hollowed-out area.

The application discloses a composite electronic element group with high integration level. The composite electronic component group comprises at least two flat element groups, wherein the at least two flat element groups are fixedly connected through a bonding dielectric layer, bonding material parts are arranged in the bonding dielectric layers, and the flat element groups are electrically connected through bonding material parts;
the flat element group comprises at least one passive multi-electrode device, and the flat element group may also be at least one of a PCB substrate or a semiconductor chip.

Preferably, the passive multi-electrode device comprises a capacitor element and a plastic package body which are horizontally arranged in an array mode, the plastic package body wraps the capacitor element, and an electrode of the capacitor element is exposed out of the surface of the plastic package body.

Preferably, the passive multi-electrode device comprises a capacitor element, a magnetic element and a plastic package body which are arranged in a horizontal array, the capacitor element is arranged on the upper surface and/or the lower surface of the magnetic element, the plastic package body wraps the capacitor element, and electrodes of the capacitor element and the magnetic element are respectively exposed out of the surface of the passive multi-electrode device.

Preferably, the passive multi-electrode device is a flat passive multi-electrode device, and the flat passive multi-electrode device is a layered capacitor, a flat magnetic element or a lamination combination of a layered capacitor and a flat magnetic element.

A power supply module comprises the abovementioned transformer unit, and further comprises a substrate and a circuit unit, wherein the transformer unit and the circuit unit are respectively arranged on two opposite sides of the substrate; and the circuit unit is electrically connected to a winding of the transformer by means of the substrate.

Compared with the prior art, the application has the following beneficial effects:

(1) The bonding dielectric layer does not need to play a supporting role, so that the thickness of the bonding dielectric layer can be far smaller than the thickness of the first lamination layer in the lamination mode, namely, the thickness is far smaller than 0.2 mm, so that the space can be saved, and on the other hand, the lamination layer above the hollowed-out area can be manufactured according to a conventional process, so that the process can be simplified.

(2) According to the application, the winding vertical section is formed through the side wall metal piece and the outer side metal piece, so that the space can be saved, meanwhile, the impedance is reduced, and the passing of a large current is facilitated.

(3) the power supply module can embed the magnetic structure by using the carrier plate, the size of the power supply module is greatly reduced, the height of the power supply module is reduced, heat dissipation is facilitated, and the wiring flexibility is improved.

(4) According to the bonding mode, due to the fact that no support is insufficient, the problems of poor filling, low compactness and the like generated during traditional lamination can be avoided, so that the reliability of the carrier plate is improved.

### BRIEF DESCRIPTION OF THE DRAWINGS

FIG. 1A to FIG. 1 B are schematic diagrams of the prior art;

FIG. 2, FIG. 3A to FIG. 3H, FIG. 4A to FIG. 4E, and FIG. 5 are schematic diagrams of Embodiment 1;

FIG. 6 and FIG. 7A to FIG. 7E are schematic diagrams of embodiment 2;

FIG. 8 to FIG. 9 are schematic diagrams of embodiment 3;

FIG. 10A to FIG. 10X are schematic diagrams of Embodiment 4;

FIG. 11A to FIG. 11J are schematic diagrams of embodiment 5;

FIG. 12A to FIG. 12B are schematic diagrams of Embodiment 6;

FIG. 13A to FIG. 13B are schematic diagrams of Embodiment 7;

FIG. 14 is a schematic diagram of embodiment 8;

FIG. 15A to FIG. 15D are schematic diagrams of Embodiment 9;

FIG. 16A to FIG. 16D are schematic diagrams of embodiment 10;

FIG. 17A to FIG. 17D are schematic diagrams of an eleventh embodiment;

FIG. 18, FIG. 19 and FIG. 20 are schematic diagrams of a twelfth embodiment;

FIG. 21A to FIG. 21C and FIG. 22A to FIG. 22D are schematic diagrams of a thirteenth embodiment;

FIG. 23A, FIG. 23B and FIG. 24A to FIG. 24C are schematic diagrams of a fourteenth embodiment;

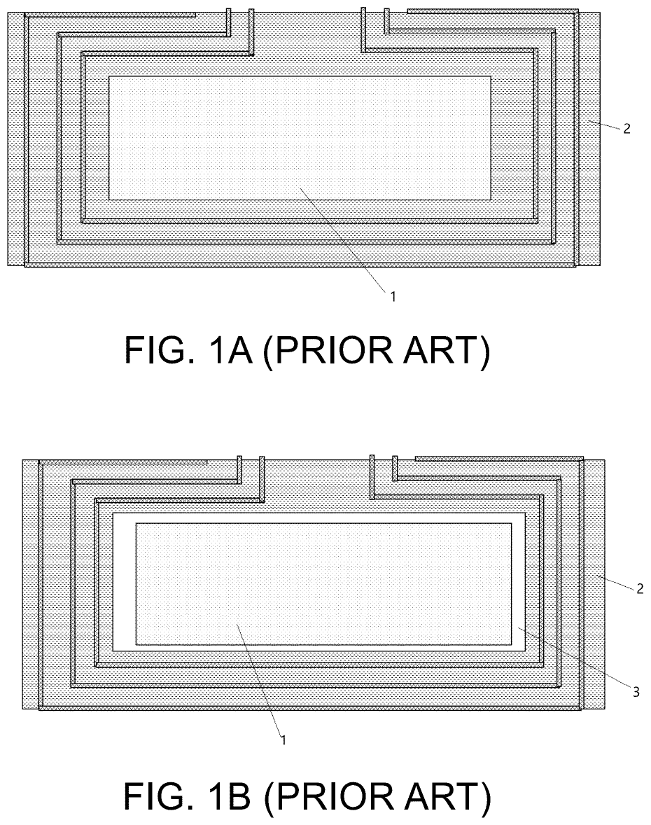

### DESCRIPTION OF THE EMBODIMENTS

The present application discloses various embodiments or examples of implementing the thematic technological schemes mentioned. To simplify the disclosure, specific instances of each element and arrangement are described below. However, these are merely examples and do not limit the scope of protection of this application. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

The core of the application is to provide the carrier plate with high integration level and the power supply module. The carrier plate can embed the magnetic structure, and the thickness of the bonding dielectric layer can be far smaller than the thickness of the lamination layer, and the winding vertical section can be formed through the side wall metal piece and the outer side metal piece, so that the flexibility of wiring is improved while the height of the power supply module is greatly reduced, heat dissipation is facilitated.

### Embodiment 1

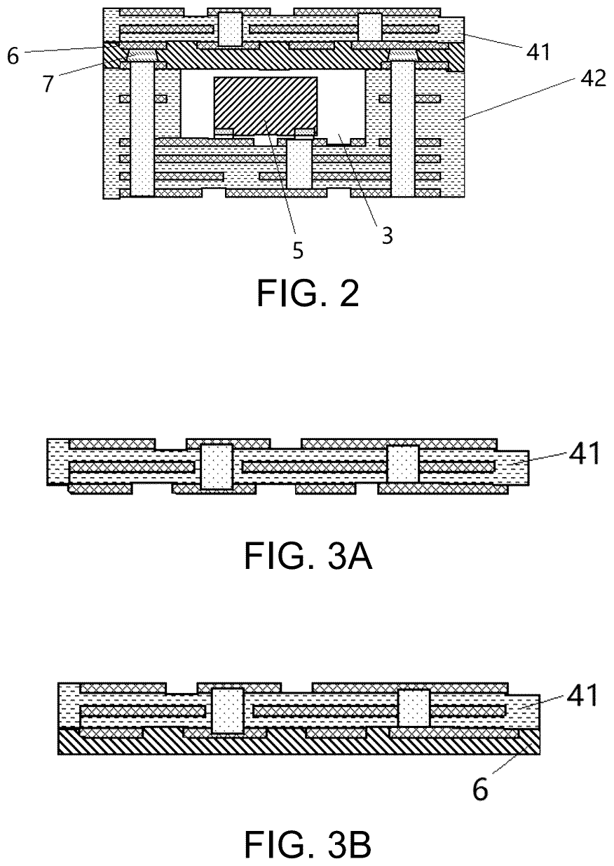

As shown in FIG. 2, the high-integration carrier plate 2 disclosed by the embodiment comprises two printed circuit board lamination layers 4 which are a first lamination layer 41 and a second lamination layer 42 respectively, the second lamination layer 42 is provided with a hollowed-out area 3, and the hollowed-out area 3 is provided with a power supply circuit assembly 5; the first lamination layer 41 and the second lamination layer 42 are fixedly connected through an insulating bonding dielectric layer 6, and the first lamination layer 41 and the second lamination layer 42 are electrically connected through a bonding material piece 7. The material of the bonding dielectric layer 6 comprises insulating dielectric materials such as a prepreg (Pre-Preg) or ABF (Ajinomoto Build-Up Film). The bonding material piece 7 is made of brazing filler metal, tin-silver alloy, tin-copper alloy, tin-silver-copper alloy, tin-antimony alloy, gold-tin alloy, high-lead solder, silver sintering slurry, copper sintering slurry, instantaneous liquid-phase sintering material or conductive slurry. By means of the bonding material, remelting cannot occur under 220° C., so that the bonding material cannot be remelted when the bonding material is applied; and the specific material can be selected by a person skilled in the art according to the requirements of the actual melting point, for example, the melting point of the tin-silver alloy, the tin-copper alloy and the tin-silver-copper alloy is about 220° C., the melting point of the tin-antimony alloy is about 240° C., and the melting point of the high-lead solder and the gold-tin alloy is about 290° C. Due to the effective constraint and protection of the insulating dielectric on the bonding material piece 7, the reliability of the bonding material piece can be effectively improved. The power supply circuit assembly 5 of the embodiment is a magnetic core 1 of the front-stage transformer; windings of the front-stage transformer are respectively arranged on the surface of the magnetic core 1 and the first lamination layer 41 and the second lamination layer 42; a winding on the surface of the magnetic core 1 is electrically connected with the bottom of the hollowed-out area 3 through a bonding material piece 7, preferably, the magnetic core I can also be fixedly connected with the bottom of the hollowed-out area 3 in a patch adhesive mode and the like. The bonding dielectric layer 6 in the embodiment does not need to play a supporting role so that the thickness of the lamination layer can be far smaller than the thickness of the first lamination layer of the lamination laminating mode, that is, the thickness is far smaller than 0.2 mm, so that the space can be saved, and on the other hand, the lamination layer above the hollowed-out area 3 can be manufactured according to a conventional process, so that the process can be simplified.

The size of the hollowed-out area 3 can be set according to the size of the power supply circuit assembly 5 in the hollowed-out area 3, and in some embodiments, the edge of at least one side of the hollowed-out area 3 to the edge of at least one side of the second lamination layer 42 can also be expanded according to actual needs.

In some other embodiments, the power supply circuit assembly 5 may also include an inductor assembly of the BUCK circuit, a capacitor assembly, a controller, a switching element, and other types of active/passive elements.

In a preferred embodiment, an insulating filling body is arranged in the hollowed-out area 3, and the insulating filling body covers the power supply circuit assembly 5.

In a preferred embodiment, when one end of the bonding material piece 7 is connected with the through hole, the through hole needs to be plated with copper on the surface after fulling the hole with the resin so as to increase the bonding area so as to reduce the connection impedance and improve the reliability of connection. Furthermore, fulling the hole with a metal slurry can be adopted, so that heat dissipation is further improved, and electric conduction is enhanced.

FIG. 3A to FIG. 3E show a manufacturing method (a first process) of the carrier plate 2 shown in FIG. 2:
S1: preparing a first lamination layer 41, as shown in FIG. 3A;
S2, arranging a bonding dielectric layer 6 on the surface of the first lamination layer 41, and performing semi-curing, as shown in FIG. 3B;
S3: opening a window on the bonding dielectric layer 6, as shown in FIG. 3C;
S4, arranging a bonding material piece 7 at the windowing position, and baking to remove the solvent, wherein as shown in FIG. 3D, the bonding material piece 7 can be a silver sintering material, a copper sintering material, an instantaneous liquid phase sintering material, conductive slurry and the like;
S5, pressing the prefabricated second lamination layer 42 (as shown in FIG. 3E) with the semi-finished product obtained in S4.

FIG. 3F to FIG. 3H show another manufacturing method of the carrier plate 2 shown in FIG. 2 (the second process):
S1: preparing a first lamination 41;
S2, a bonding material piece 7, such as brazing filler metal, is arranged on the surface of the first lamination layer 41, and the shape of the bonding material piece can also be hemispherical and the like after backflow;
S3, arranging a bonding dielectric layer 6 on the surface of the first lamination layer 41, and performing semi-curing, as shown in FIG. 3G;
S4, windowing is performed on the bonding dielectric layer 6, as shown in FIG. 3H, in some other embodiments, the window opening width can be slightly wider than that of the bonding material piece 7 so as to ensure that the surface of the bonding material piece 7 is fully exposed;
S5: pressing the prefabricated second lamination layer 42 (as shown in FIG. 3E) with the semi-finished product obtained in S4.

In some other embodiments, the bonding dielectric layer 6 and the bonding material piece 7 may also be generated on the second lamination layer 42, and at this time, the bonding dielectric layer 6 may not be provided at the hollowed-out area. In some other embodiments, the bonding material piece 7 may be formed by further bonding two bonding material sub-pieces respectively disposed on the first lamination layer 41 and the second lamination layer 42. In a preferred embodiment, the two bonding material sub-pieces may be the same material. In another preferred embodiment, the two bonding material sub-pieces are different materials, for example, one side is a silver sintering material, a copper sintering material, an instantaneous liquid-phase sintering material or conductive slurry, and one side is a brazing filler metal; or one side is a component A of an instantaneous liquid-phase sintering material, and one side is a component B of an instantaneous liquid-phase sintering material

As shown in FIG. 4A, in a preferred embodiment, the carrier plate 2 comprises a through hole metal piece 8 penetrating through the first lamination layer 41 and the second lamination layer 42, and the through hole metal piece 8 can be used for forming an electrical connection between two prefabricated printed circuit board lamination layers.

As shown in FIG. 4B, in a preferred embodiment, the second lamination layer 42 comprises a second metal piece penetrating through the second lamination layer 42, and the corresponding position of the first lamination layer comprises a first metal piece (equivalent to a dotted line frame in the figure) arranged in the blind hole; and the second metal piece, the first metal piece and the bonding material piece 7 between the second metal piece and the first metal piece jointly form a longitudinal interconnection section. The outer layer can be further lamination above the first lamination layer 41 and used for forming other electrical interconnection structures.

As shown in FIG. 4C, in a preferred embodiment, the hollowed-out area 3 in the carrier plate 2 is provided with the step area 10, so that the wiring flexibility is improved, the space is fully utilized, the elements 5 with different heights are carried, for example, the inductor of the BUCK circuit is generally high, and the input and output capacitors are generally small in height.

As shown in FIG. 4D, in a preferred embodiment, the device further comprises a third lamination layer 43, and after the third lamination layer 43 realizes interlayer interconnection with the first lamination layer 41 through the bonding dielectric layer 6 and the bonding material piece 7, the first lamination layer 41 and the second lamination layer 42 are interconnected. In this way, the flexibility of wiring can be further improved.

As shown in FIG. 4E, in a preferred embodiment, a winding is not arranged on the surface of the magnetic core 1, the windings are both arranged in a combined body formed by the first lamination layer 41 and the second lamination layer 42, and at the moment, the magnetic core 1 does not need to be electrically interconnected with the surface of the hollowed-out area 3.

As shown in FIG. 5, in a preferred embodiment, two power supply circuit assemblies 5 are arranged in the hollowed-out area 3, and are respectively arranged on the surface of the first lamination layer 41 and the bottom surface of the hollowed-out area 3 of the second lamination layer 42. The positions of the two power supply circuit assemblies 5 in the vertical direction overlap. Preferably, the upper power supply circuit assembly 5 can be fixedly connected with and electrically connected with the first lamination layer 41 through the patch adhesive and the conductive connecting material 7 respectively. The gap between the two power supply circuit assemblies 5 in the vertical direction can also be provided with a bonding adhesive to realize thermal coupling. In some other embodiments, when the two power supply circuit assemblies 5 are vertical devices, electrical interconnection can be achieved by arranging a conductive material in a gap between vertical devices.

### Embodiment 2

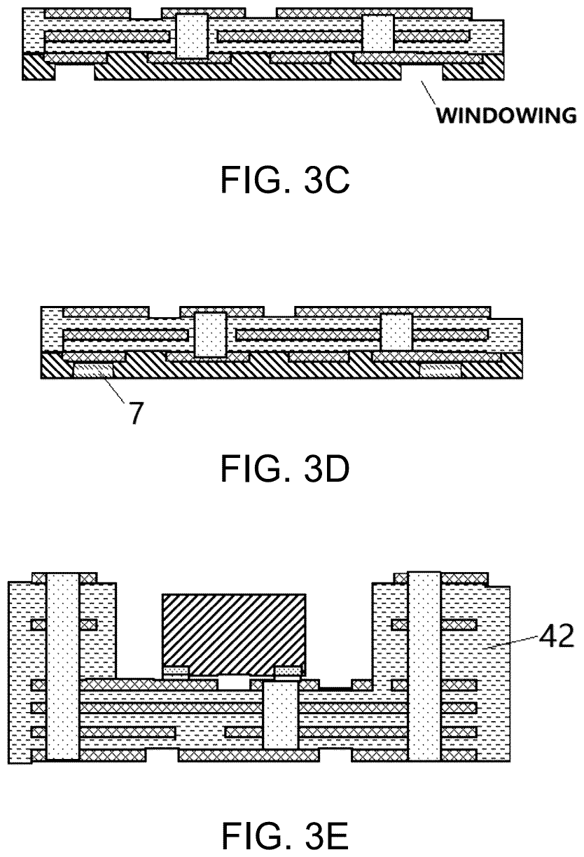

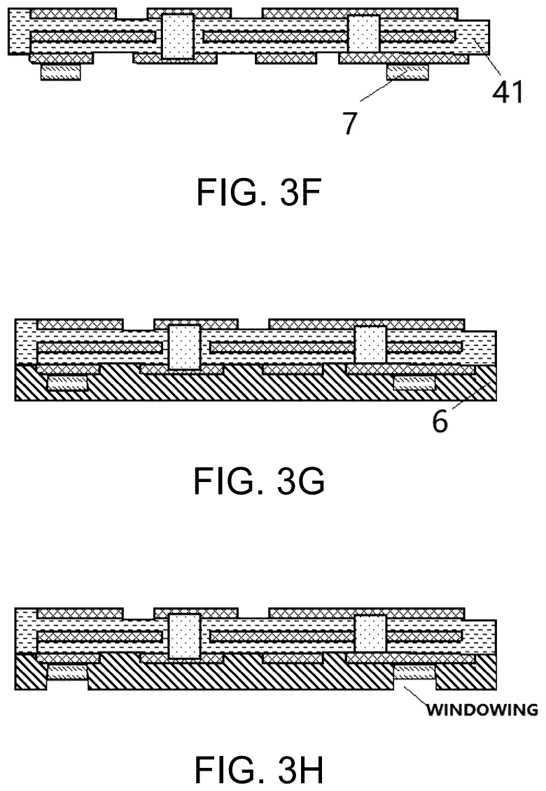

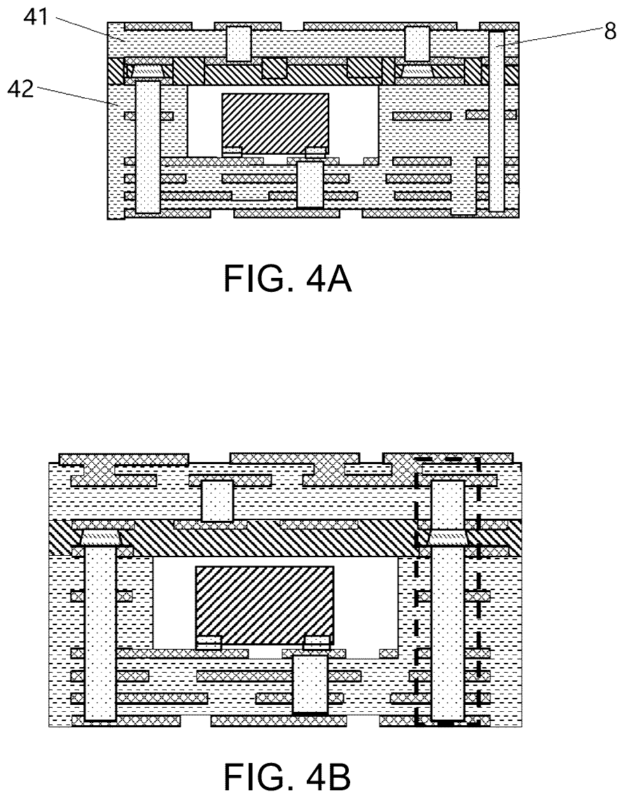

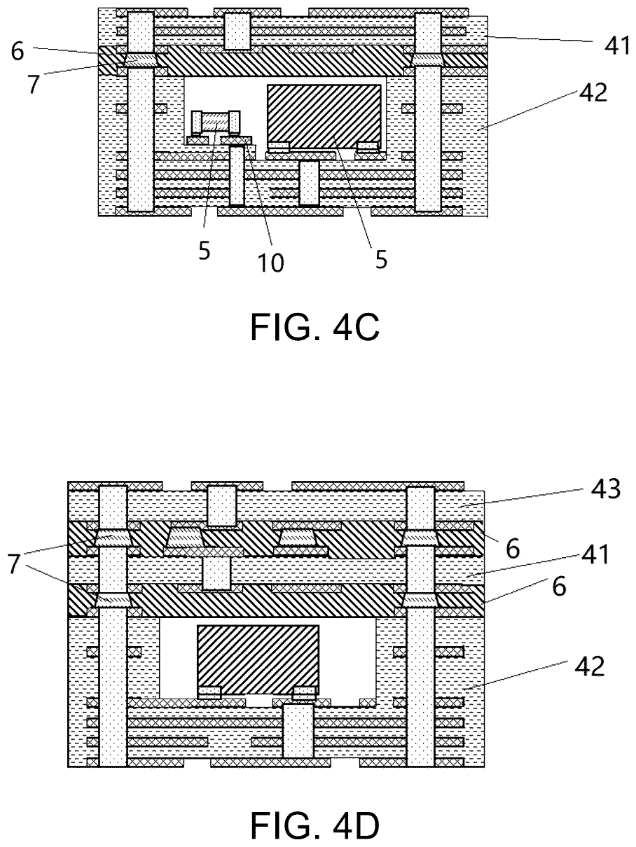

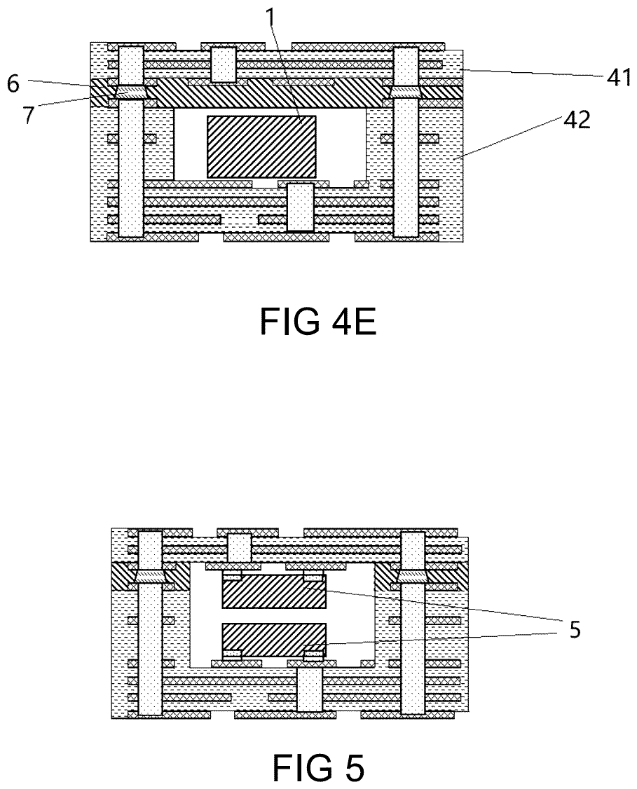

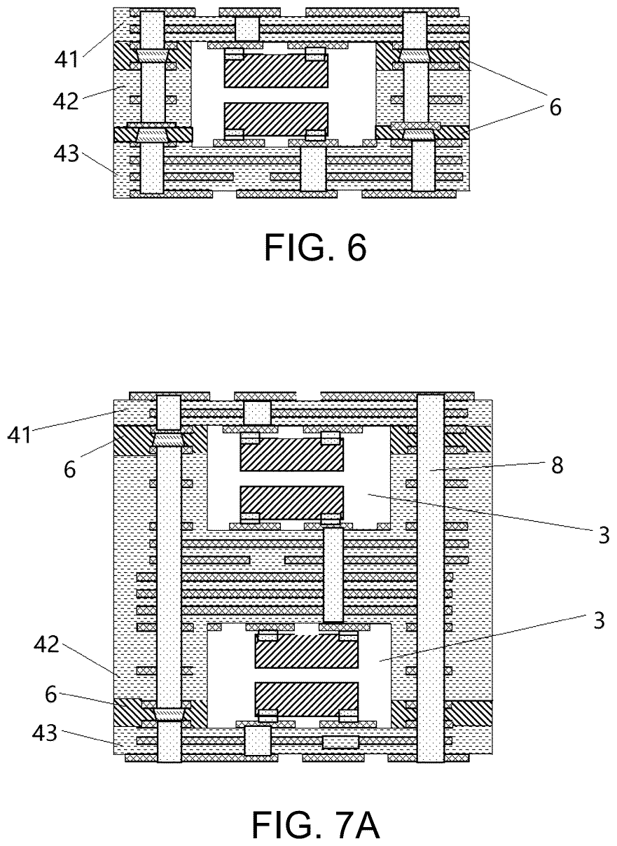

As shown in FIG. 6, the carrier plate 2 of the embodiment comprises a first lamination layer 41, a second lamination layer 42 and a third lamination layer 43, the first lamination layer 41 and the second lamination layer 42 realize interlayer interconnection through the bonding dielectric layer 6 and the bonding material piece 7, and the second lamination layer 42 and the third lamination layer 43 realize interlayer interconnection through the bonding dielectric layer 6 and the bonding material piece 7. The inter-layer interconnection mode is the same as that of the first embodiment. In the embodiment, the hollowed-out area 3 penetrates through the second lamination layer 42, so that the power supply circuit assembly 5 can be arranged on the surfaces of the first lamination layer 41 and the third lamination layer 43, and installation operation is easy to realize on a plane.

In some other embodiments, the carrier plate 2 may include an N-layer printed circuit board lamination layer 4 and an N-1 layer of adhesive dielectric layer 6.

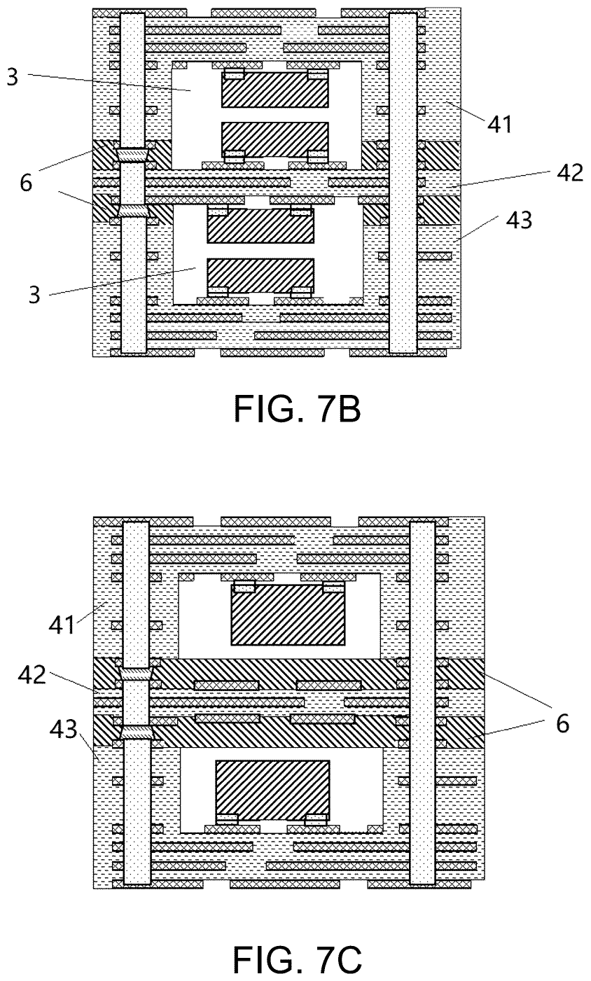

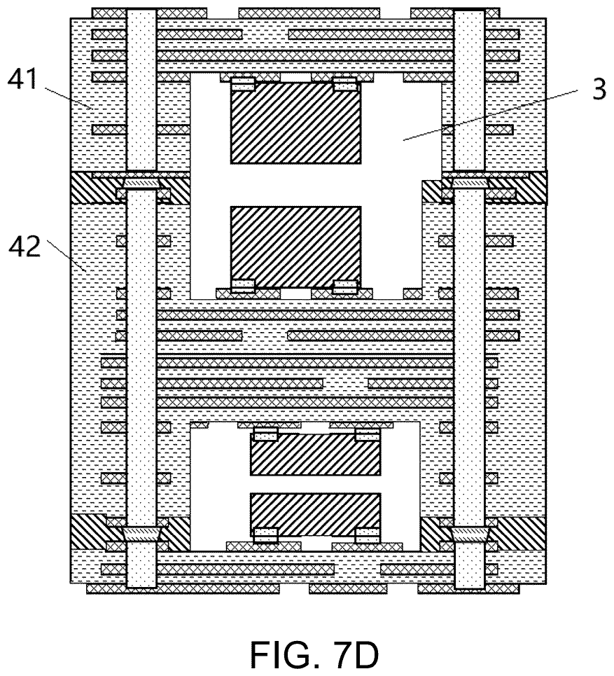

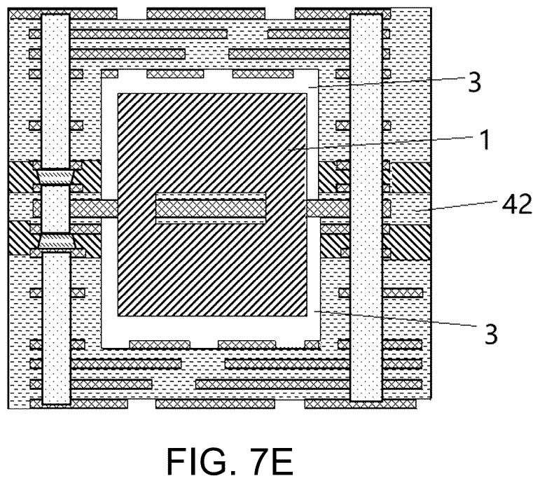

As shown in FIG. 7A, in a preferred embodiment, the two surfaces of the second lamination layer 42 are respectively provided with two hollowed-out areas 3 which are not communicated with each other, and the two hollowed-out areas 3 can be respectively provided with the corresponding power supply circuit assemblies 5. The through-hole metal pieces 8 penetrating through the through-hole metal pieces 8 of the whole carrier plate 2 and/or only the through-hole metal pieces 8 penetrating through the single lamination layers can be arranged according to actual conditions.

In a preferred embodiment, as shown in FIG. 7B, the difference between the present embodiment and FIG. 7A lies in that the hollowed-out area 3 is respectively arranged on the first lamination layer 41 and the third lamination layer 43, the second lamination layer 42 is not hollowed out, and only the power supply circuit assembly 5 is arranged at a position corresponding to the hollowed-out area.

In a preferred embodiment, as shown in FIG. 7C, the surface of the second stack 42 is not provided with the power supply circuit assembly 5, but only plays an intermediate interconnection role.

In a preferred embodiment, as shown in FIG. 7D, two hollowed-out areas 3 are respectively arranged on the first lamination layer 41 and the second lamination layer 42, and the two hollowed-out areas 3 are communicated to form a finished area which can be used for accommodating a higher power supply circuit assembly 5.

In a preferred embodiment, as shown in FIG. 7E, the power supply circuit assembly 5 is a magnetic core 1, which penetrate through the second lamination layer 42; and the magnetic core 1 are arranged in the two hollowed-out are 3 on the two sides of the second lamination layer 42 (the magnetic core 1 can comprise two magnetic core pieces which penetrate through the second lamination layer 42 and are arranged on two sides of the second lamination layer 42, the magnetic core piece can be U-shaped or E-shaped or the like, or the magnetic core 1 can also be arranged in a U-shaped or E-shaped shape), the second lamination layer 42 is mainly used for arranging a thick copper wiring winding, and the part of the second lamination layer 42 can be reduced in thickness or trimmed in the horizontal direction through milling and the like so as to improve the space utilization rate. Preferably, an auxiliary winding parallel to the thick copper wiring winding (serving as a main winding) can be further arranged in the second lamination layer 42, the auxiliary winding is used for forming leakage inductance, the width of the auxiliary winding is set to be smaller than that of the main winding, and the auxiliary winding can be arranged into a second lamination layer 42 or a thin copper layer on the surface of the second lamination layer 42.

### Embodiment 3

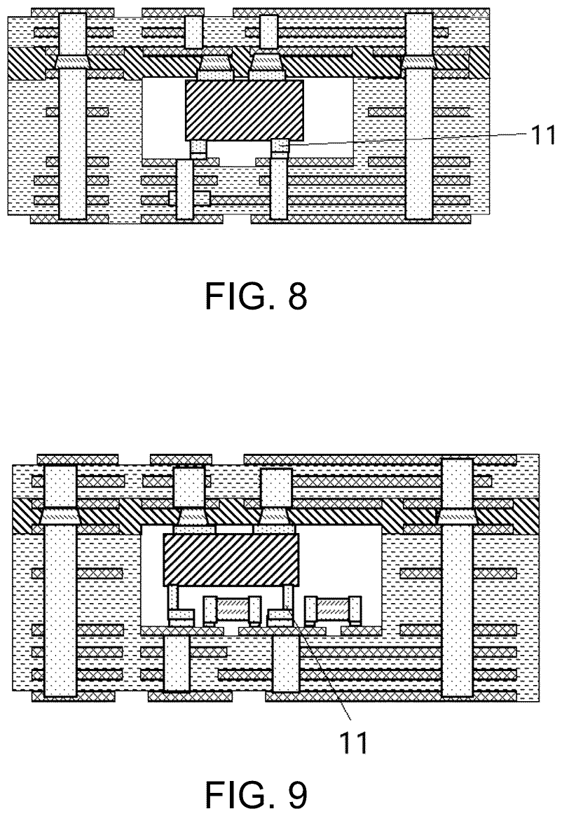

As shown in FIG. 8, the difference between the embodiment and the first embodiment lies in that one power supply circuit assembly 5 in the embodiment is electrically interconnected with the surface of the first lamination layer 41 and the bottom of the hollowed-out area 3 through the pins 11. Preferably, the pins 11 can be leveled by a brush grinding process and a lamination surface. In some embodiments, the power supply circuit assembly 5 is an inductor, and two ends of the winding are respectively fan-out on the upper surface and the lower surface.

In a preferred embodiment, metalized semi-counterbores are arranged at positions corresponding to the pins 11 in the first lamination layer 41 and the second lamination layer 42, so that the connecting area is increased, and the tolerance in the height direction is absorbed.

As shown in FIG. 9, in a preferred embodiment, at least a part of the pin 11 is an elastic pin, and the elastic pin is used for absorbing a height tolerance. Preferably, the power supply circuit assembly 5 in the hollowed-out area 3 can be arranged in a stacked mode, and a power supply circuit assembly 5 (such as a patch capacitor and the like) with a lower height is arranged in a space below the power supply circuit assembly 5 corresponding to the pin 11, so that the horizontal size of the unit is further reduced.

### Embodiment 4

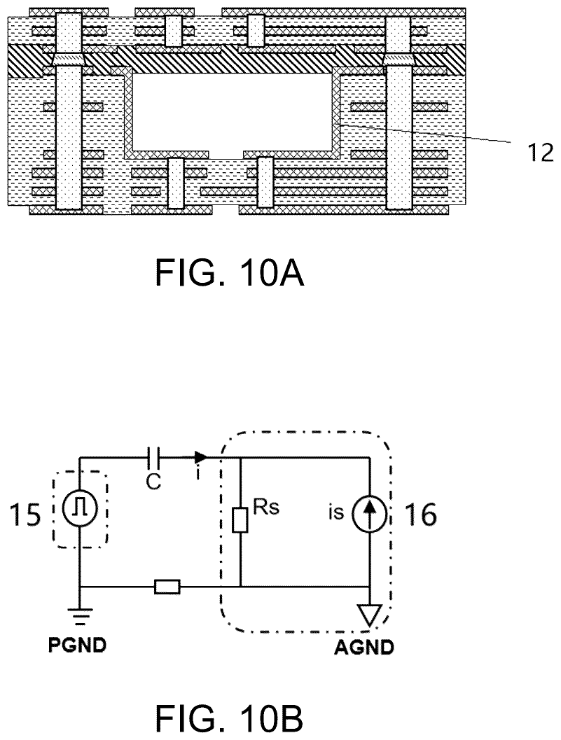

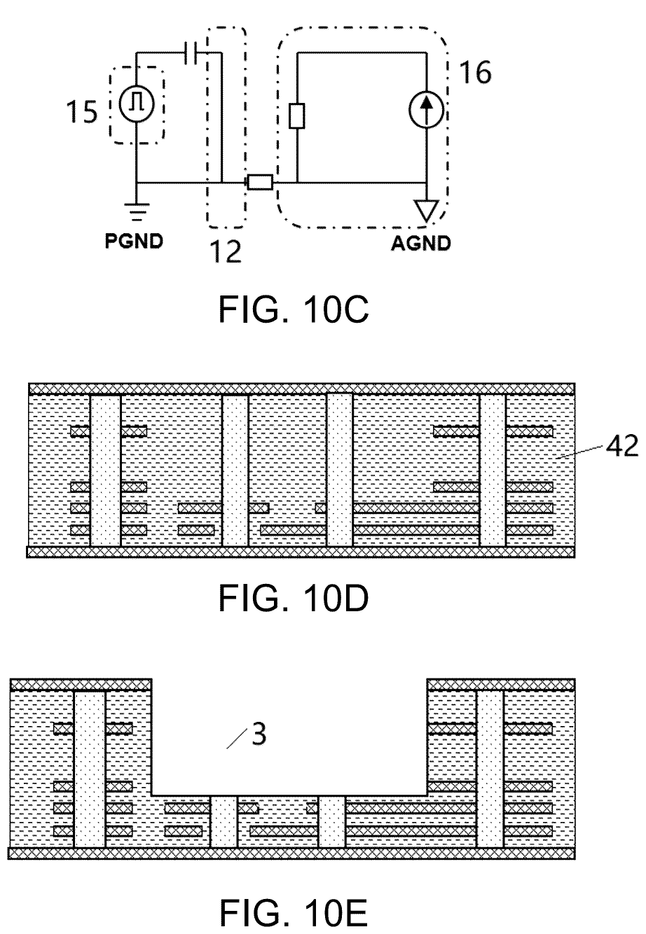

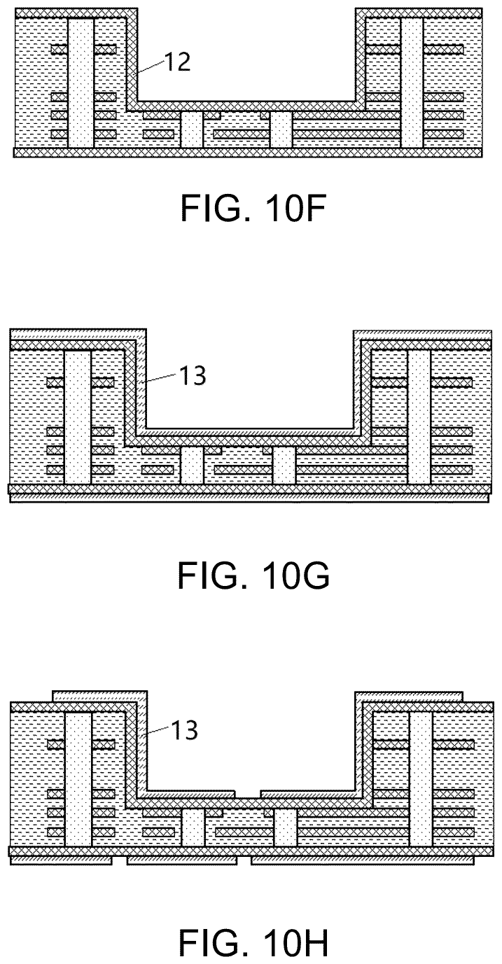

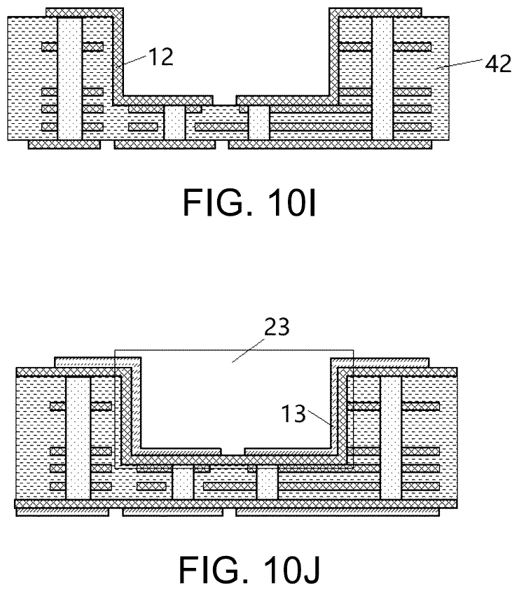

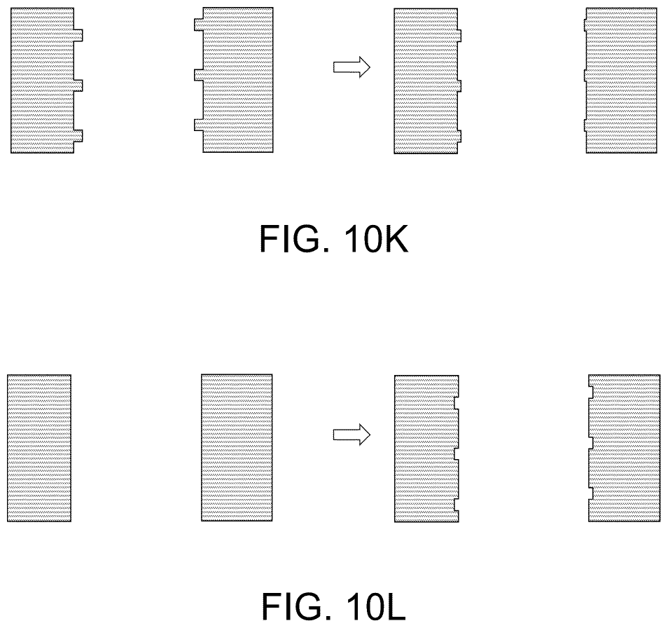

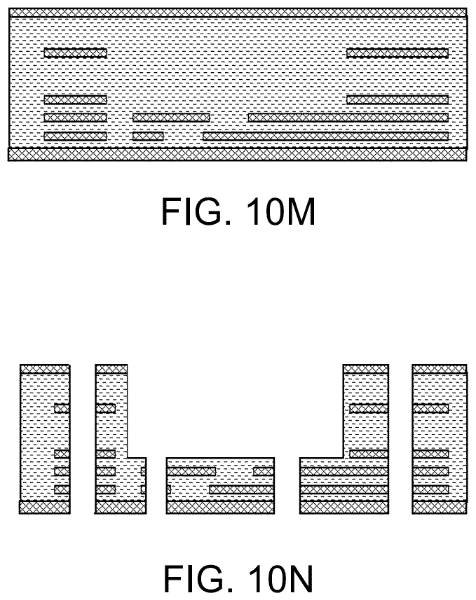

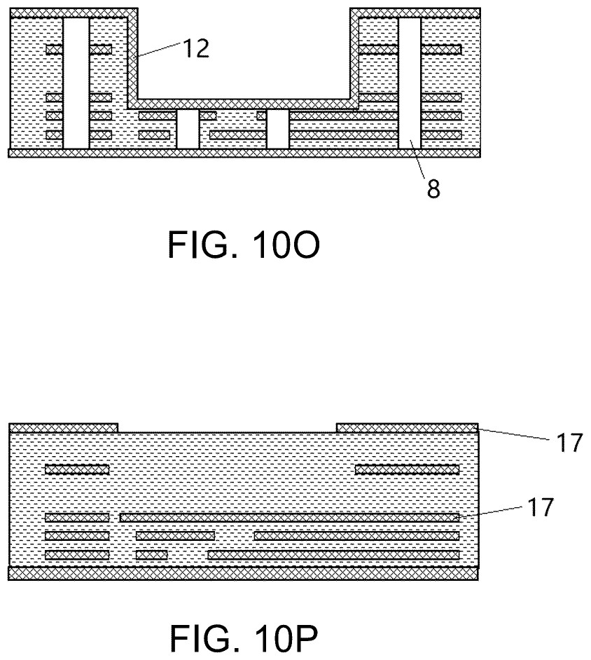

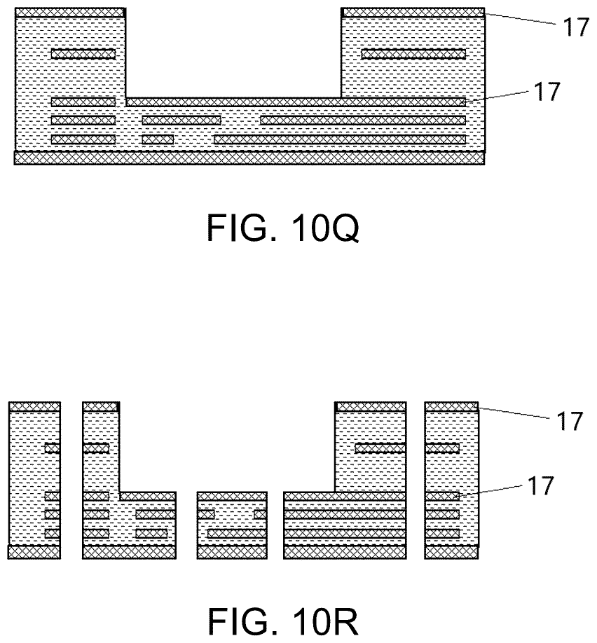

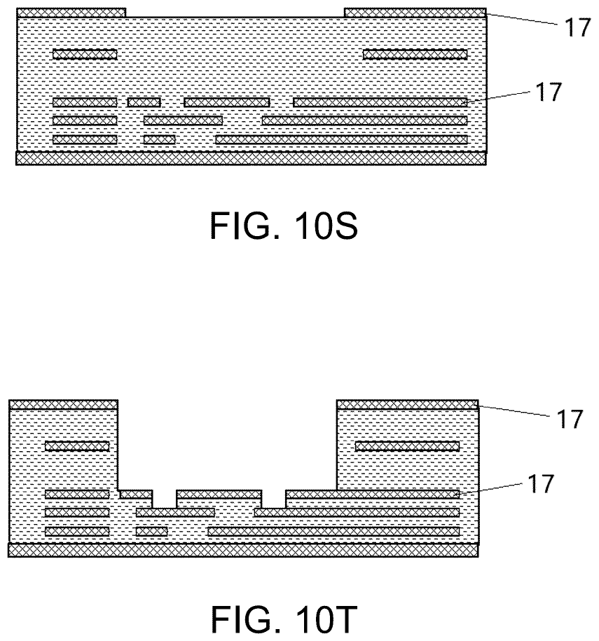

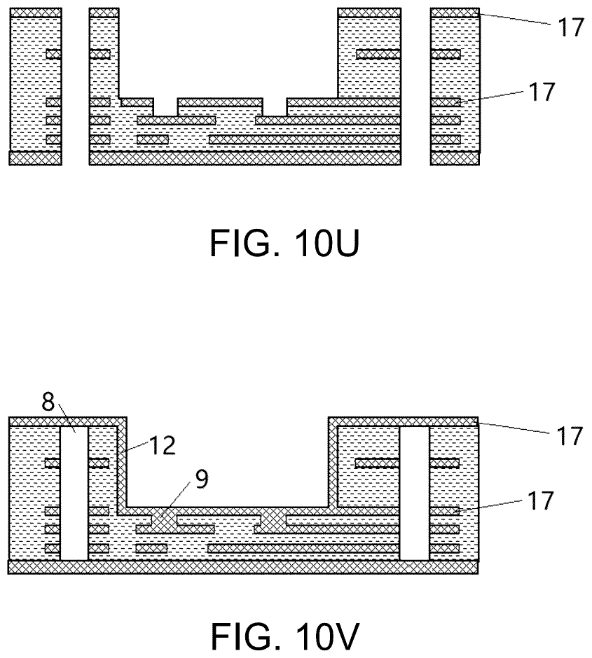

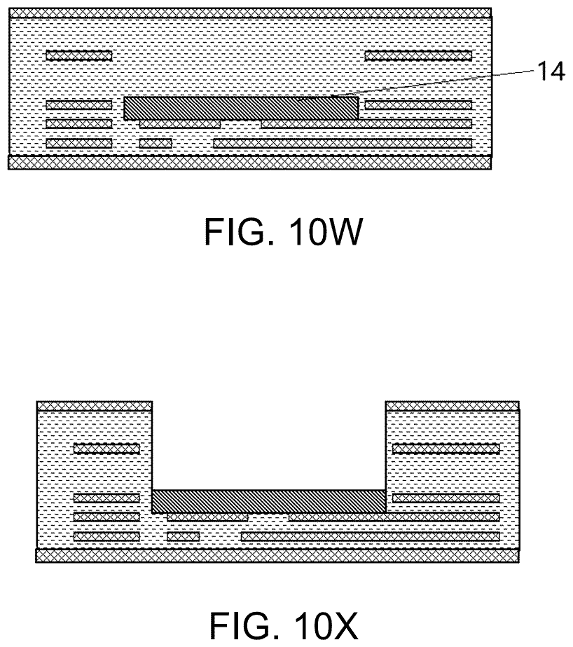

As shown in FIG. 10A, the difference between the embodiment and the first embodiment lies in that the hollowed-out area 3 of the embodiment is provided with a side wall metal piece 12 (which is a convenient diagram, the power supply circuit assembly 5 is not shown in the figure), and the side wall metal piece 12 can be used for being electrically connected, thermally connected or forming a signal shielding layer and the like. In the embodiment, the side wall metal piece 12 is electrically connected with the surface wiring metal of the hollow area 3 through a metallization process.

The principle of the signal shielding layer is shown in FIG. 10B to FIG. 10C, FIG. 10B is a common signal interference transmission path, a parasitic capacitor exists between the interference source 15 (such as a switch waveform) and the sampling circuit 16, and the jump signal is subjected couple the interference current to the sampling circuit through the parasitic capacitor, so that the sampling signal is interfered. In FIG. 10A, the hollowed-out area 3 usually places a part of an inductor or an inductor, and the inductor serves as an interference source 15 and interferes with an external signal. The side wall of the hollowed-out area 3 is metalized, and the metal is connected to a relatively stable potential, such as a power supply or a ground wire of Vin, GND, Vout, VDD and the like, so that an interference coupling path can be cut off, and as shown in FIG. 10C, interference of an interference source 15 in the cavity to an external signal is eliminated. The side wall metal can also shield the high-frequency Loop, the Loop inductance is reduced, and the external interference of the carrier plate 2 system is reduced.

In some other embodiments, the side wall metal pieces 12 on the same side wall of the hollowed-out area 3 are divided into a plurality of side wall metal pieces 12 with different electrical properties and used for being connected with different electrodes, and preferably, each side wall metal piece 12 extends in the thickness direction of the carrier plate 2. The segmentation mode is not limited to etching, milling, drilling and the like.

FIG. 10D to FIG. 10I show a manufacturing method of the second lamination layer 42 of the carrier plate 2 of the present embodiment:
S1: preparing a prefabricated product of a second lamination layer 42 to be hollowed out, as shown in FIG. 10D;
S2, the prefabricated product is hollowed out to form a hollowed-out area 3, and as shown in FIG. 10E, the hollowed-out part can be mechanically cut;
S3, performing surface metallization on the hollowed-out area 3 to preliminarily form side wall metal pieces 12 connected with the bottoms of the hollowed-out areas 3 and outside of the hollowed-out areas 3, as shown in FIG. 10F;
S4: forming an anti-etching layer 13, as shown in FIG. 10G;
S5, performing pattern definition, removing a part of the anti-etching layer 13 according to a preset pattern, and exposing a copper pattern needing to be etched, as shown in FIG. 10H;
S6: etching and removing the etch-resistant layer 13 to obtain a second laminate 42, as shown in FIG. 10I.

In the step S3, the surface metallization can metalize the whole prefabricated product, and can also be used for metallizing the bottom surface and the side edge of the hollowed-out area 3 under the protection of the pattern;

In step S4, the anti-etching layer 13 may be a metal anti-etching layer such as Sn, Ni, and Au deposited by a metallization process.

In the embodiment, the specific method for graphic definition in the step S5 is as follows:
S5.1: firstly, laser direct writing is only performed on the anti-etching layer 13 in the solid line area 23 in FIG. 10J (i.e., the side wall and the bottom surface of the hollowed-out area 3, and the area of the upper surface adjacent to the side wall, the proximity width being less than 1 mm);
S5.2, carrying out pattern definition on the front and back surfaces by using photosensitive resin, and defining an anti-etching layer pattern.

The sequence of steps S5.1 and S5.2 can be interchanged, for example, the pattern of the anti-etching layer 13 on the upper surface and the lower surface is defined through photosensitive resin protection, then the pattern of the anti-etching layer 13 in the red dotted line frame is defined through laser direct writing, and then perform the remaining steps. The depth of the hollowed-out area 3 is greater than ½ focal length of the laser, preferably greater than one focal length, so as to avoid mutual interference in the processing process of the exposed surface in the surface and the hollowed-out area 3.

In step S5.1, the anti-etching layer 13 of the side wall can also be subjected to graph segmentation in a mechanical cutting mode, and at the moment, a micro-convex structure can be preset on the side wall of the anti-etching layer 13, and then drilling/milling removal is carried out, as shown in FIG. 10K; or the anti-etching layer 13 can be directly milled and removed, as shown in FIG. 10L. FIG. 10K and FIG. 10L are top views of the second lamination layer 42, and only show the anti-etching layer 13 at the height position where the lamination surface outside the hollowed-out area 3 is located.

FIG. 10M to FIG. 10O show another embodiment of steps S1 to S3, and the steps of a via metallization process and a surface metallization process are combined:
S1-1: preparing a prefabricated product of a second lamination layer 42 to be hollowed out and provided with a through hole as shown in FIG. 10M;
S2-1: performing mechanical cutting to form a hollowed-out structure and a penetrating through hole, as shown in FIG. 10N;
S3-1, performing surface metallization to form a through hole metal piece 8 and a side wall metal piece 12, as shown in FIG. 10O;

The subsequent process is similar to the manufacturing method, and details are not described herein again.

In a preferred embodiment, part of the through holes in the hollowed-out area 3 cannot be subjected to a plugging-hole process to form a natural exhaust channel.

FIG. 10P to FIG. 10R show another embodiment of steps S1-1 to S2-1:
S1-2: preparing a preform as shown in FIG. 10P, wherein a metal barrier layer 17 is provided on the preform (for a part that does not need to be hollowed out, the metal barrier layer 17 is provided on the surface of the preform; for a region to be hollowed out, the metal barrier layer 17 is provided inside the preform, and a bottom portion of the hollowed-out region 3 is formed in a subsequent step);
S2-2: grooving, such as laser, plasma and the like, removing the residual dielectric layer through a surface window until the metal barrier layer 17 is exposed, as shown in FIG. 10Q; performing mechanical cutting to form a through hole, as shown in FIG. 10R; in some embodiments, removing most of the depth of material in a mechanical mode, and then exposing the metal barrier layer 17 by laser ablation, plasma grinding and the like

The subsequent process is similar to the manufacturing method, and details are not described herein again.

FIG. 10S to FIG. 10V show another embodiment of steps S1-1 to S3-1:
S1-3: preparing a preform as shown in FIG. 10S, wherein a metal barrier layer 17 is provided on the preform (for a part that does not need to be hollowed out, the metal barrier layer 17 is provided on the surface of the preform; for the area to be hollowed out, the metal barrier layer 17 is provided inside the preform, and in a subsequent step, the bottom of the hollowed-out area 3 and the bottom of the blind hole of the hollowed-out area 3) are formed);
S2-3: slotting, and using a pattern preset at the bottom to serve as a self-aligned pattern of laser and plasma removal media, as shown in FIG. 10T, and forming a blind hole at the position of a blind hole reserved on the metal barrier layer 17 at the bottom of the hollow area 3; mechanically cutting to form a through hole, as shown in FIG. 10U;
S3-3, performing surface metallization to form a through hole metal piece 8, a blind hole metal piece 9 and a side wall metal piece 12, as shown in FIG. 10V;

The subsequent process is similar to the manufacturing method, and details are not described herein again.

FIG. 10W to FIG. 10X show another embodiment of steps S1-1 to S2-1:
S1-4: preparing a preform as shown in FIG. 10W, wherein a peelable layer 14 is provided inside the preform;
S2-4: milling to a peelable layer 14, as shown in FIG. 10X; peeling off the peelable layer 14, manufacturing a through hole, forming a structure similar to that of FIG. 10N, and being used for subsequent manufacturing steps.

### Embodiment 5

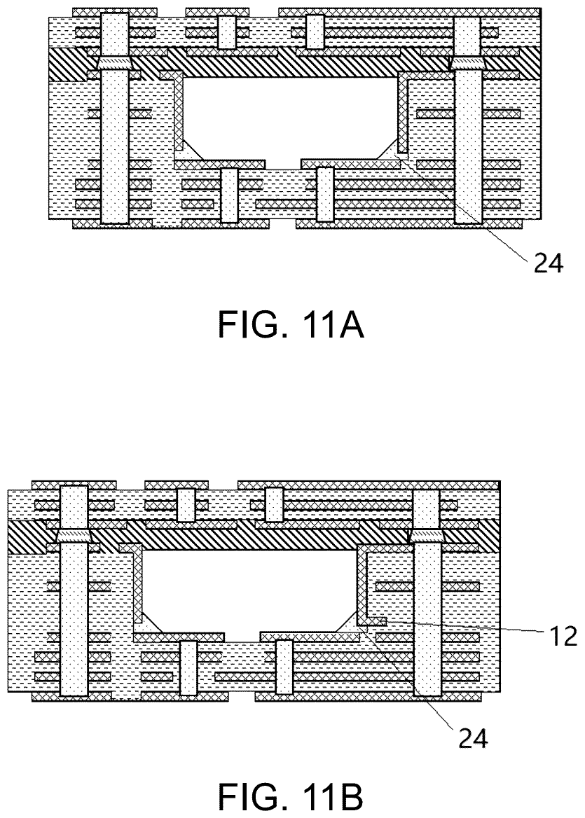

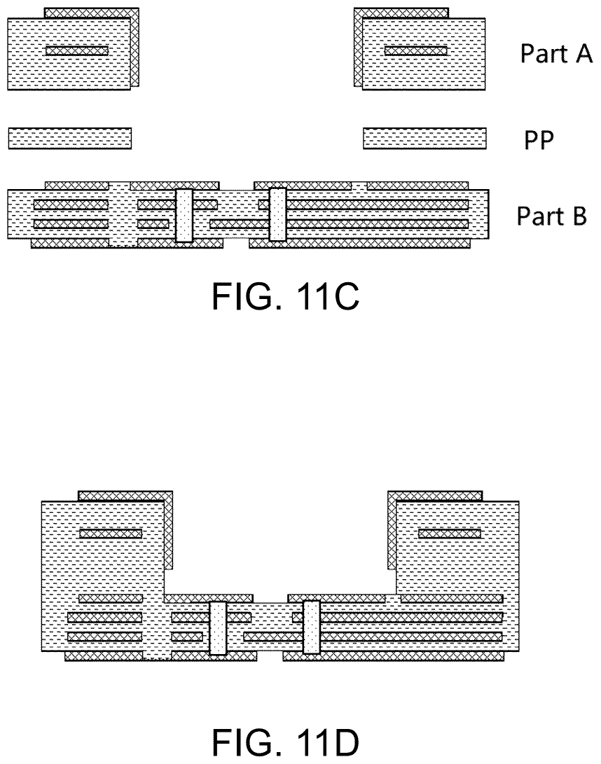

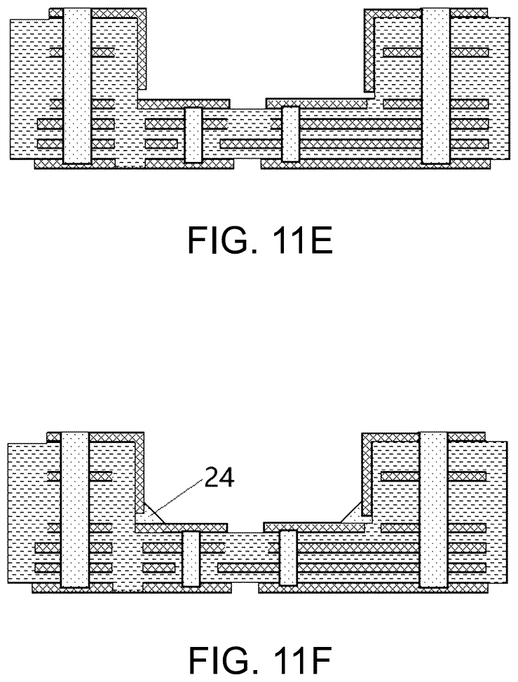

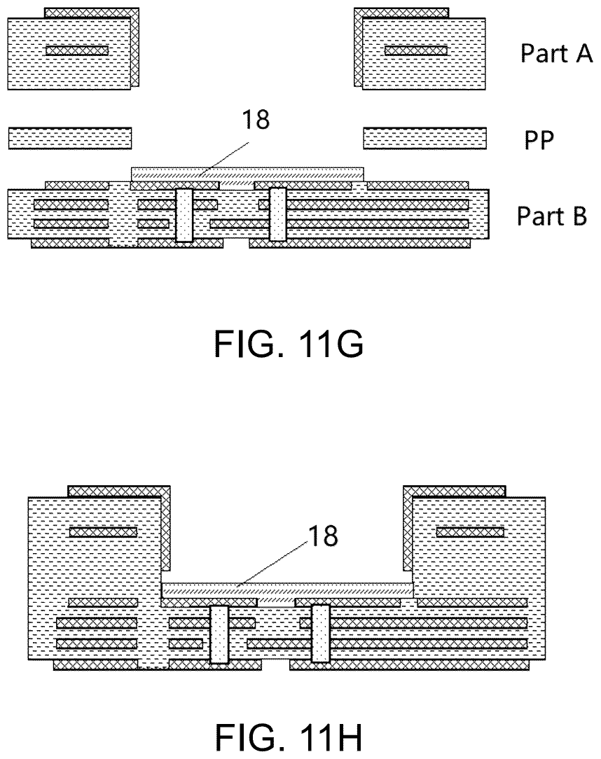

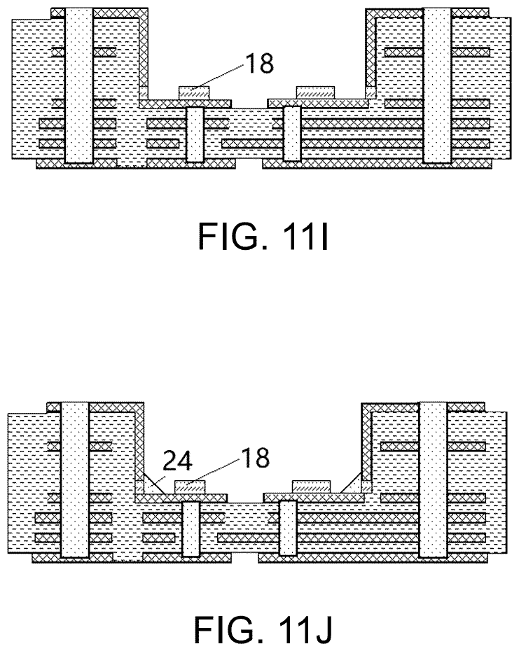

The difference between the embodiment and the fourth embodiment lies in that as shown in FIG. 11A, the wiring layer at the bottom of the side wall metal piece 12 and the bottom of the hollowed-out area 3 is further electrically connected through a conductive material 24, such as brazing filler metal, conductive paste, a sintering material and the like, so that the electrical connection impedance can be reduced. As shown in FIG. 11B, the upper end of the side wall metal piece 12 may not extend on the upper surface of the second lamination layer 42, or may further extend transversely on the upper surface, and the side wall metal piece 12 may also be electrically connected to other electrical interconnection structures inside the second lamination layer. FIG. 11C to FIG. 11F show a manufacturing method of the present embodiment:
S1, preparing a three-part prefabricated part as shown in FIG. 11C, wherein the part A is hollowed through in a penetrating mode and the hollowed-out area 3 is provided with a laminated sub-part with a side wall metal plating layer, the part B is a laminated sub-part without a hollowed-out area, and the middle part of the laminated sub-part is laminated through a hollowed-out PP layer to obtain a complete prefabricated product as shown in FIG. 11D;
S2, drilling, surface metallization and graphic definition, the implementation mode is similar to the forementioned embodiment, details are not described herein again, and finally a lamination layer which is not electrically connected with the bottom of the side wall of the hollowed-out area 3 shown in FIG. 11E is finally formed;
S3: electrically connecting the side wall metal member 12 to the bottom of the hollow region 3 by means of a conductive material 24, as shown in FIG. 11F.

FIG. 11G to FIG. 11J show another manufacturing method of the embodiment:
S1-1, preparing a three-part prefabricated part as shown in FIG. 11G, wherein the part A is a lamination sub-part which is hollowed through in a penetrating mode (the side wall of the hollowed-out area 3 is not metalized), the part B is a lamination sub-part with an anti-chemical coating 18 arranged at the corresponding position of the hollowed-out area 3, and the middle of the lamination sub-part is lamination by a hollowed-out PP layer to obtain a complete prefabricated product as shown in FIG. 11H;
S2-1, drilling, surface metallization and graphic definition, and simultaneously metallizing the side wall of the hollowed-out area 3 in the surface metallization process According to the embodiment, the forementioned embodiment is similar to the embodiment, details are not described herein again, and further, the anti-chemical plating 18 is windowing, as shown in FIG. 11I;
S3-1: electrically connecting the side wall metal piece 12 to the bottom of the hollowed-out area 3 by means of brazing filler metal, as shown in FIG. 11J.

### Embodiment 6

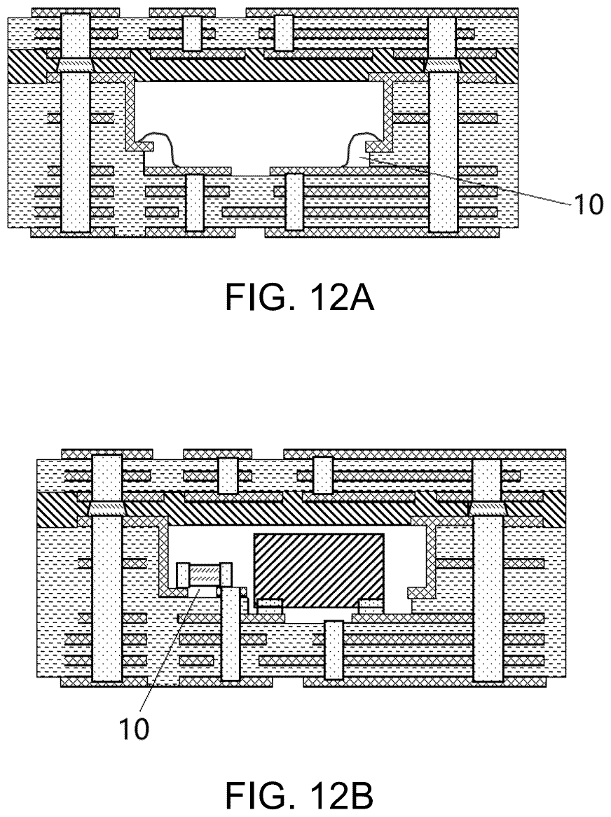

The difference between the embodiment and the fourth embodiment lies in that as shown in FIG. 12A, the side wall of the hollowed-out area 3 is provided with a step area 10, the surface of the step area 10 is covered with a metal layer, and the step area 10 is electrically connected with the wiring layer at the bottom of the hollowed-out area 3 in a metal jumper mode and the like.

In a preferred embodiment, as shown in FIG. 12B, the step area 10 is further provided with a power supply circuit assembly 5 with a relatively low height, a metallization layer for electrical connection may be provided at the side wall of the edge of the step area 10, or there is no metallization layer at the side wall of the edge of the step area 10.

### Embodiment 7

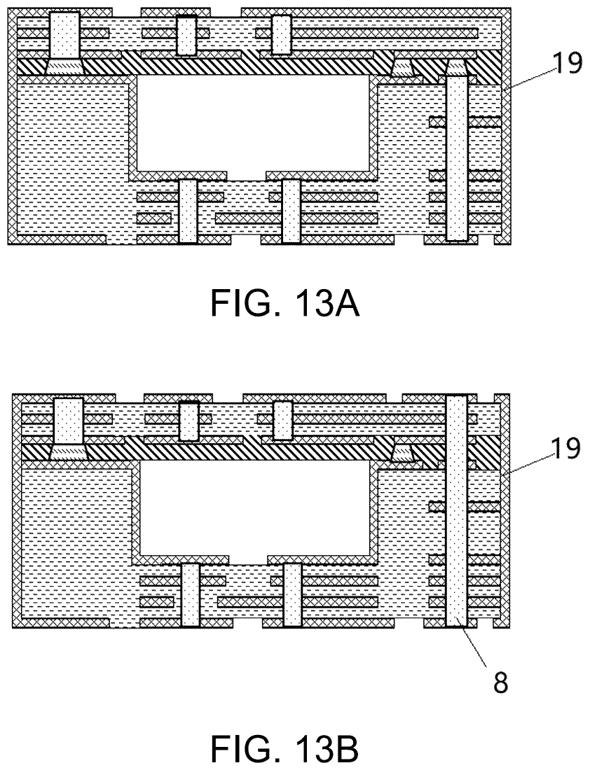

The difference between the embodiment and the fourth embodiment lies in that in addition to the fact that the side wall metal piece is arranged in the hollowed-out area 3, an outer side metal piece 19 is also arranged on the outer side wall of the carrier plate 2, as shown in FIG. 13A, the horizontal size is further reduced, and the flow capacity, the heat dissipation capacity and the like are improved.

In a preferred embodiment, as shown in FIG. 13B, the second laminate 42 can be provided with a through-hole metal piece 8 penetrating the entire carrier plate 2, the first lamination layer 41 or the second lamination layer 42 at a corresponding position of the outer side metal piece 19, and the through-hole metal member 8 can be used for being electrically connected to the outer side metal piece 19 to further reduce impedance.

### Embodiment 8

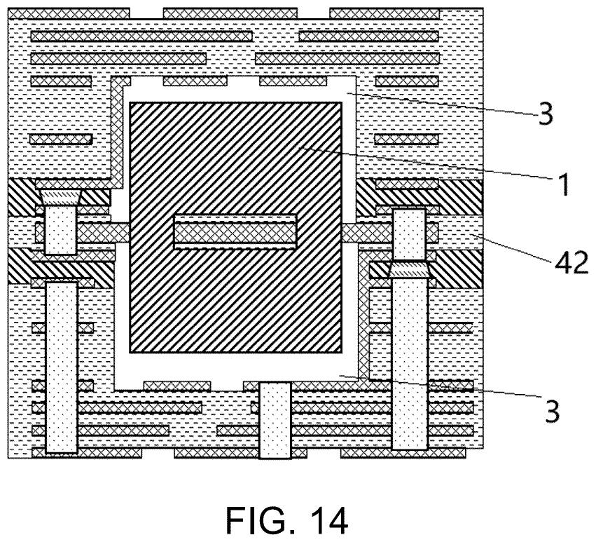

The embodiment is a combination of Embodiment 2 (FIG. 7E) and Embodiment 4. As shown in FIG. 14, the two adjacent hollowed-out areas 3 are internally provided with a cross-lamination magnetic core 1 (the magnetic core 1 is formed by buckling a magnetic core assembly), the middle second lamination layer 42 is used for arranging thick copper wiring to form a winding, and windings surrounding the upper/lower half part of the magnetic core 1 are respectively fan-out towards the upper and lower surfaces in the upper/lower hollowed-out area 3 through the side wall metal piece 12 and the through hole metal piece 8.

### Embodiment 9

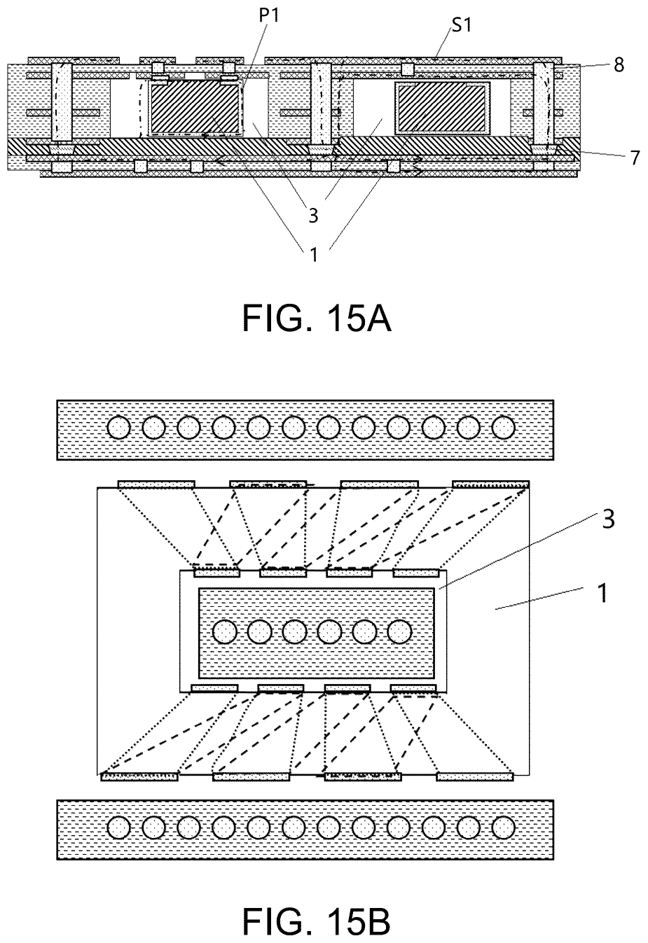

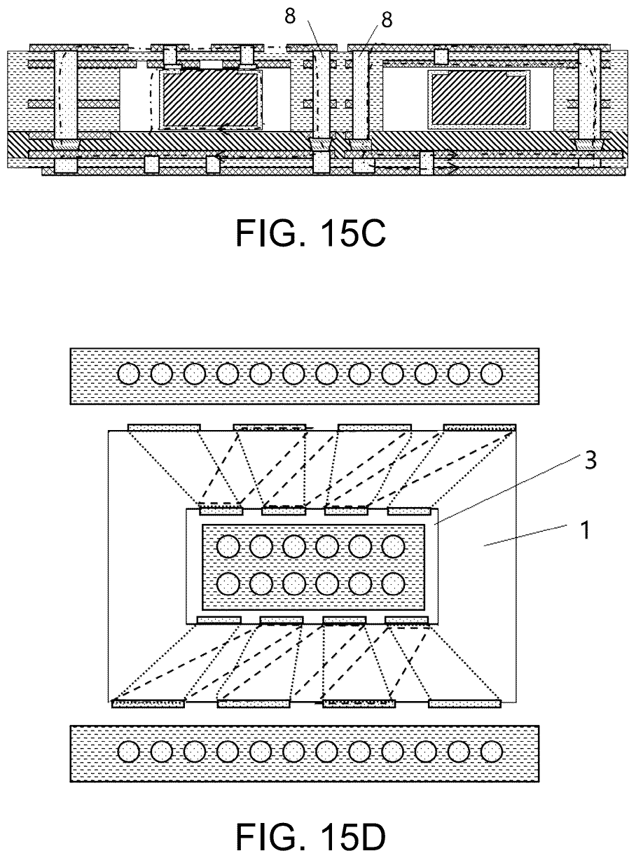

The present embodiment differs from Embodiment 1 in that the magnetic core 1 is an annular magnetic core; meanwhile, the hollowed-out area 3 accommodating the magnetic core 1 is an annular area; as shown in FIG. 15A and FIG. 15B (FIG. 15B is a top view of the cross section at the height of the hollowed-out area 3, and the area marked by the dotted line is a primary winding part wound around the upper and lower surfaces of the magnetic core 1), the winding surrounding the magnetic core 1 comprises a primary winding (P1), a first secondary winding (S1), and the primary/secondary winding is at least one circle around the magnetic core 1. During application, the primary/secondary windings can be respectively connected in series with corresponding switch elements (the switch elements can be arranged on the surface of the carrier plate 2). The primary winding is arranged on the surface of the magnetic core 1, the two ends of the primary winding are electrically connected with the first lamination 41 or the second lamination 42, and the primary winding is led out to the surface of the carrier 2 through the electrical interconnection structure in the first lamination 41 and/or the second lamination 42. In a preferred embodiment, the insulating stress buffer layer can be arranged between the primary winding and the magnetic core arranged on the outer side of the magnetic core, and the functions of stress buffering (preventing loss of the magnetic core), insulation enhancement, adhesion and fixation and the like can be achieved.

In the embodiment, the secondary winding is formed by an electrical interconnection structure of the first lamination layer 41 and the second lamination layer 42, wherein the horizontal section is of an in-layer electric interconnection structure, and the vertical section is a through hole metal piece 8 and a bonding material piece 7.

In a preferred embodiment, the primary winding arranged on the surface of the magnetic core can realize series or parallel connection of part of windings through the transition connection of the first lamination layer 41 or the second lamination layer 42. The secondary windings may also be connected in parallel by multilayer wiring within the stack to reduce impedance.

It should be noted that, for the transformer, the so-called primary/secondary side is a relative concept and does not specifically specify special attributes, so that the designation of the primary/secondary winding in the embodiment can be interchanged.

In some other embodiments, the secondary winding may be disposed around two to four sides of the magnetic core (generally the magnetic core is a “port” shape having four sides). In some other embodiments, the magnetic core is annular.

In some other embodiments, when the current of the primary winding is large, the primary winding is arranged on the surface of the magnetic core through a metallization process, flat wire winding and the like, and the primary winding can be directly wound with a circular wire when the number of turns of the primary winding is greater than 10 turns or even 30 turns.

In some other embodiments, the periphery of the periphery of the magnetic core is provided with an opening on the side wall of the carrier plate for exhausting gas so as to ensure the reliability of temperature circulation of the carrier plate and the like.

In some other embodiments, the periphery of the periphery of the magnetic core is wrapped by the carrier plate, and at the moment, an exhaust hole can be formed in the surface of the carrier plate, so that the reliability of temperature circulation and the like of the carrier plate is ensured.

In addition, when the leading-out end of the primary winding is fan-out through the inter-layer interconnection fan-out, part of the interference area can be formed between the leading-out end of the primary winding and the secondary winding, and a person skilled in the art can avoid through reasonable layout on the planar area.

In a preferred embodiment, as shown in FIG. 15C and FIG. 15D (FIG. 15D is a top view of a cross section at a height of the hollowed-out area 3), a part of the first secondary winding located in the middle of the annular area does not share a vertical section.

### Embodiment 10

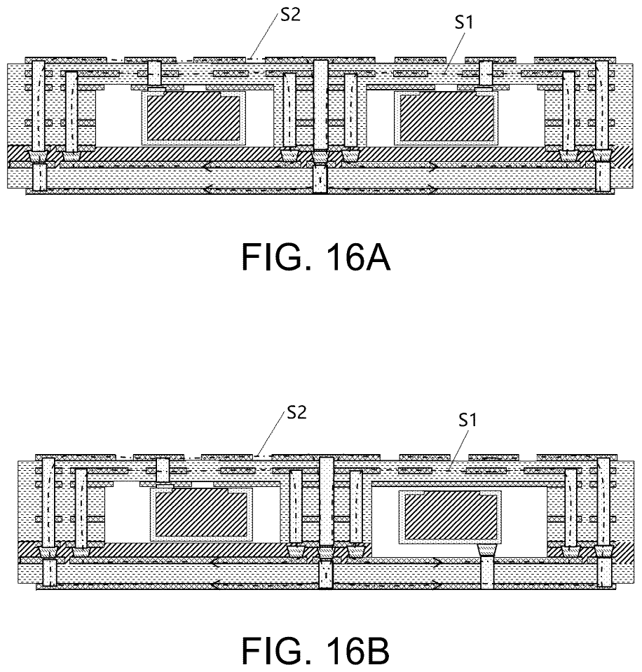

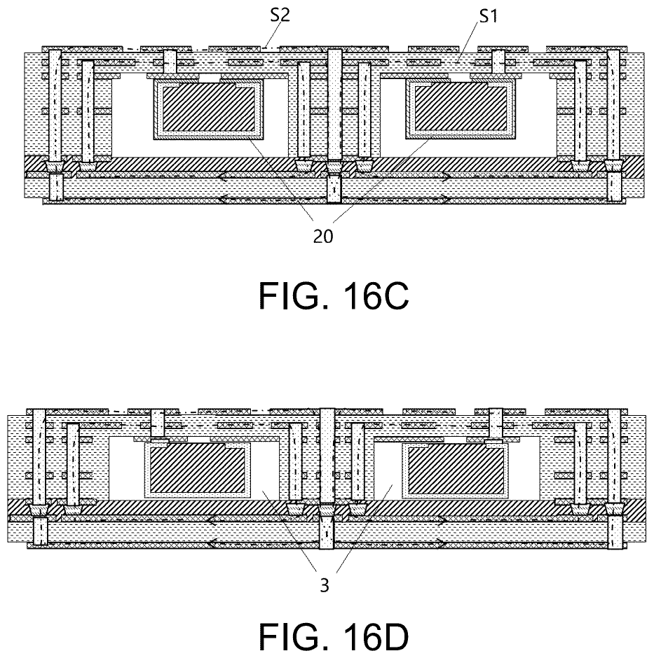

The difference between the embodiment and Embodiment 9 lies in that as shown in FIG. 16A, the embodiment further comprises a second secondary winding, and the second secondary winding is arranged outside the first secondary winding. Since the first secondary winding surrounds the inner side of the second secondary winding, the first secondary winding does not share a vertical section in the middle of the annular area, and the second secondary winding can share a vertical section in the middle of the annular area, or may not share the vertical section.

Similarly, more primary/secondary windings can be arranged outside the second secondary winding, or more primary/secondary windings are arranged between the first secondary winding and the second secondary winding, and a person skilled in the art can set the primary/secondary windings according to actual needs. The winding arranged at the outermost layer can directly use the surface of the carrier plate 2 to form the transverse section of the winding, and other windings (including the primary/secondary winding) can lead the terminal out of the surface of the carrier plate 2 through the electrical interconnection structure.

In a preferred embodiment, as shown in FIG. 16B, at least one pair of terminals of a primary/secondary winding integrated with the magnetic core 1 is led out to the upper surface of the plate 2 through the first lamination layer 41, and the other is led out to the lower surface of the plate 2 through the second lamination layer 42.

In a preferred embodiment, as shown in FIG. 16C, an insulating layer 20 is arranged on the surface of the magnetic core 1, and the insulating layer 20 covers the winding arranged on the surface of the magnetic core 1 at the same time.

In a preferred embodiment, when the primary/secondary winding has a high-voltage insulation requirement, the entire hollowed-out area 3 can be used as a high-voltage side, as shown in FIG. 16D, glue pouring can also be performed in the hollow area 3, and the glue pouring is mainly used for coating the magnetic core 1 (and other high-voltage side elements arranged in the hollowed-out area 3) and corresponding electrical connection sites.

### Embodiment 11

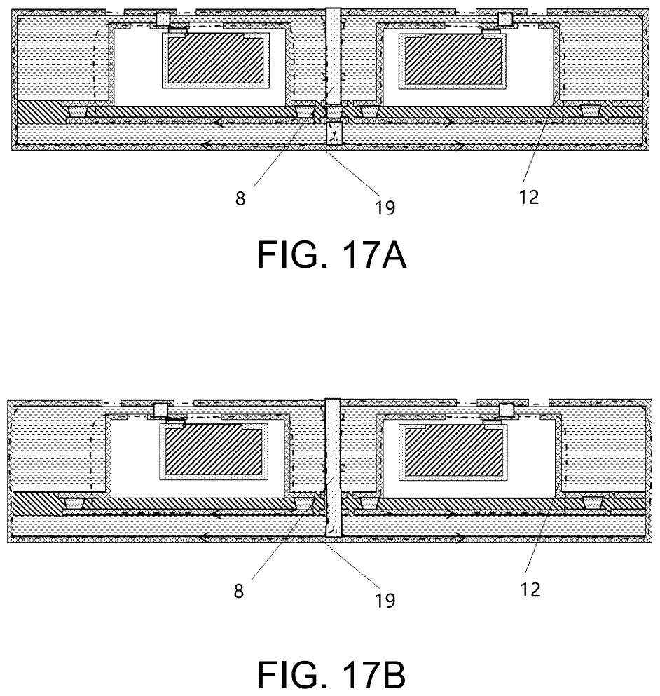

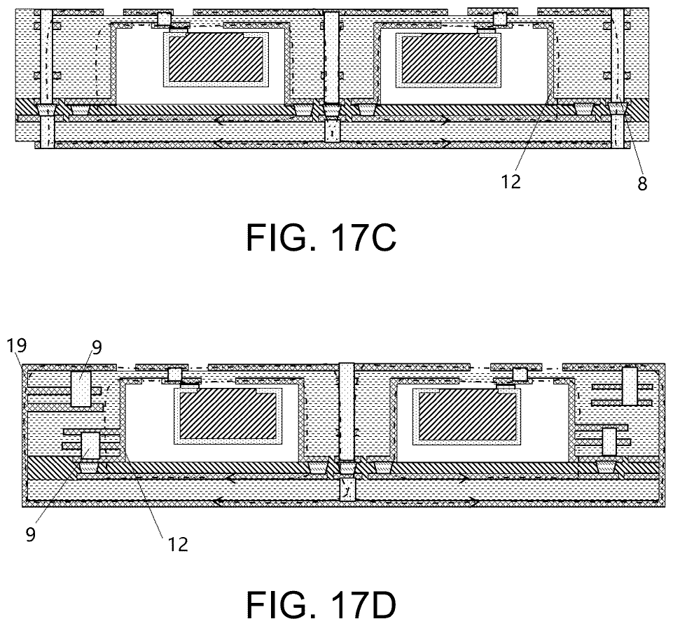

The difference between the embodiment and the embodiment 10 is that the primary winding and the first secondary winding of the embodiment form at least a part of the vertical section through the side wall metal piece 12 and the outer side metal piece 19, as shown in FIG. 17A, only the vertical section of the second secondary winding in the middle of the annular area is a common through hole metal piece 8, and the other secondary side winding vertical sections are all side wall metal pieces 12 or outer side metal pieces 19, so that the space utilization rate of the carrier plate 2 can be further improved, and the impedance is reduced.

In a preferred embodiment, as shown in FIG. 17B, the through hole metal piece 8 shared by the middle vertical section is a via hole, so that the space utilization rate of the carrier plate 2 can be further improved, and the impedance is reduced. In another preferred embodiment, one or more wiring layers can be lamination on the surface layer to integrate control and drive wiring, and the power connection points of the primary and secondary windings correspond to the packaging of the connected switching elements. By means of the staggered arrangement, wiring limitation caused by packaging of the switching devices can be effectively avoided, and the connection impedance of the power loop is reduced.

In some other embodiments, as shown in FIG. 17C, only the side wall metal piece 12 and the vertical section of the second secondary side winding can be formed through the through hole metal piece 8.

In a preferred embodiment, as shown in FIG. 17D, blind hole metal pieces 9 are arranged adjacent to the adjacent corresponding positions of the side wall metal pieces 12/outer side metal pieces 19 in the first lamination layer 41/the second lamination layer 42, and the blind hole metal pieces 9 are connected in parallel with the corresponding side wall metal pieces 12/outer side metal pieces 19, so that the space utilization rate is further improved, and the parasitic impedance is reduced. A person skilled in the art can flexibly set the position of the parallel structure according to actual conditions.

### Embodiment 12

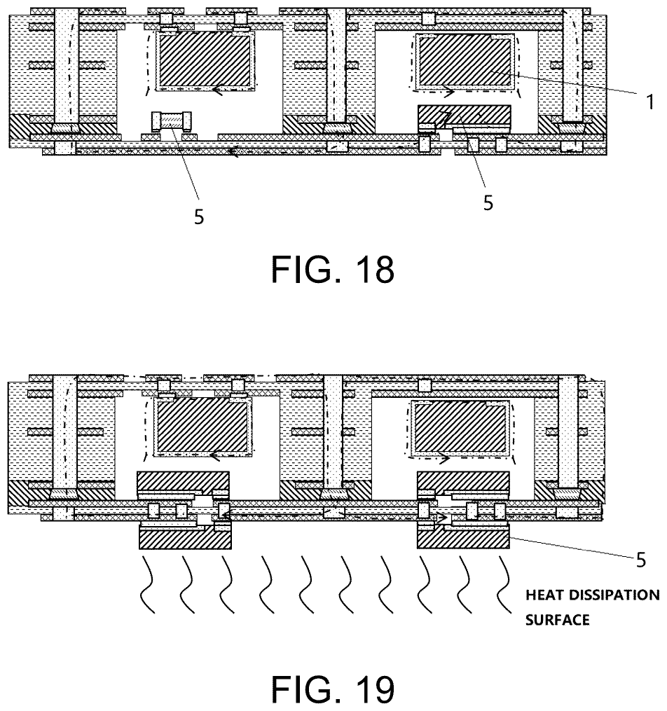

The difference between the embodiment and the tenth embodiment lies in that; as shown in FIG. 18, in addition to the magnetic core 1, the power supply circuit assembly 5 arranged in the hollowed-out area 3 can further comprise a resistance-capacitance element, a driving element, a controller and the like, and can also comprise a switching element connected in series with the winding. Other power supply circuit assemblies 5 can be placed in a stack with the magnetic core 1.

In a preferred embodiment, an element generating a relatively large heating value, such as a switch element connected in series with a winding, can be thermally connected to the outside by means of a thermal via hole or the like, and can also have the functions of electrical and thermal connection at the same time. Preferably, in addition to the thermal via holes, a metal strip-shaped copper or even a local heat sink (copper embedding block) can be used to realize electrical and thermal connection with the outside.

In a preferred embodiment, as shown in FIG. 19, in order to further reduce the impedance, the switching elements connected in series with the winding usually adopt a plurality of parallel connection modes, at the moment, one switch element (represented by the power supply circuit assembly 5) can be arranged in the hollowed-out area 3, and the other switch element is arranged at the corresponding position of the surface of the carrier plate 2 to be arranged in pairs. Preferably, the thickness of the laminated layer provided with the switching elements should be reduced as much as possible to minimize the conduction thermal resistance to the heat dissipation surface (e.g., a double-sided PCB that does not include an internal transverse wiring layer). Preferably, the switch element arranged on the surface of the carrier plate 2 can adopt double-sided heat dissipation (back-exposed metal) devices.

In a preferred embodiment, as shown in FIG. 20, the surface of the magnetic core 1 is not electrically interconnected with the lamination layer, and the primary/secondary winding is realized through an electrical interconnection structure in the lamination layer and between the lamination layers. Preferably, the magnetic core 1 can be fixed in the hollowed-out area 3 by means of a bonding material.

### Embodiment 13

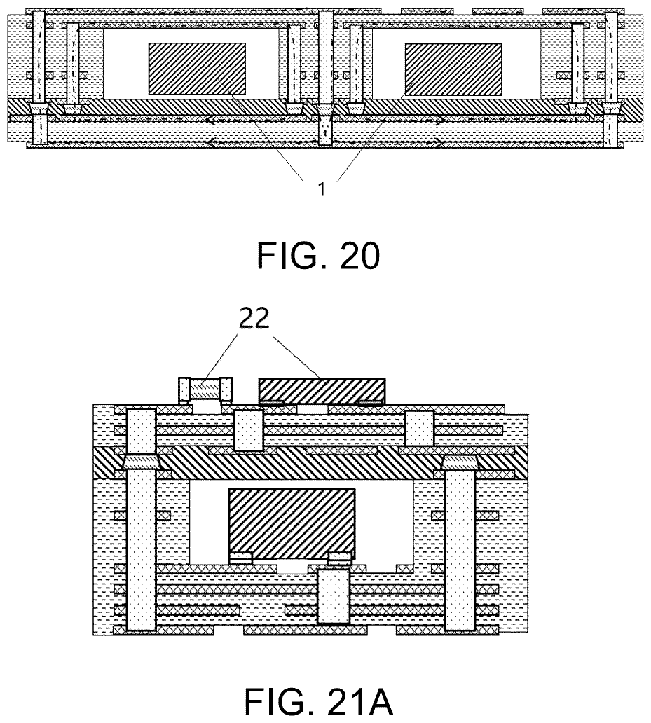

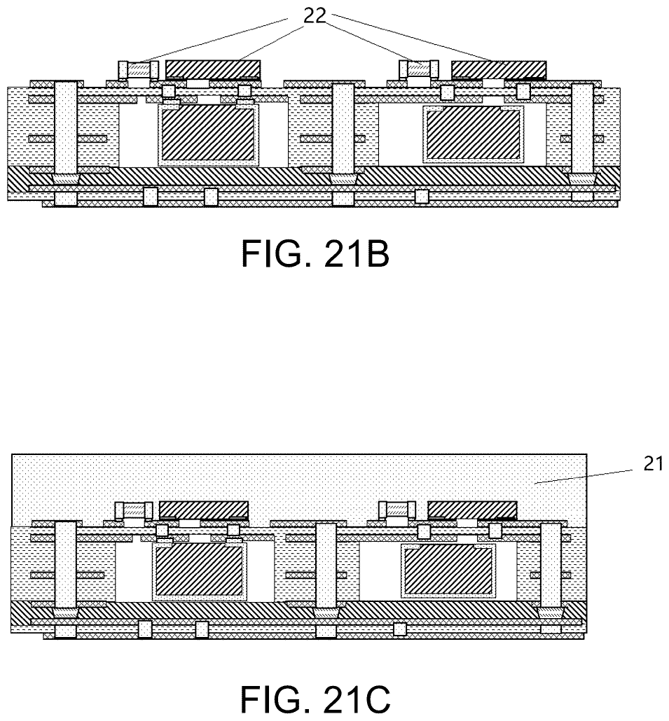

According to the embodiment, the surface of the carrier plate 2 of the embodiment is further provided with the other circuit elements 22 to form a power supply module; the circuit element 22 comprises various active/passive elements, such as a capacitor element, a driving element, a controller, a switch element, etc., and the circuit element can be directly arranged on the surface of the carrier plate 2, as shown in FIG. 21A and FIG. 21B. Preferably, the surface of the carrier plate 2 can be encapsulated to form a plastic package body 21 (in other embodiments, the plastic package body 21 can also be a glue-filling protector formed by glue-filling), and is used for protecting the circuit element and improving the voltage-withstanding performance, as shown in FIG. 21C.

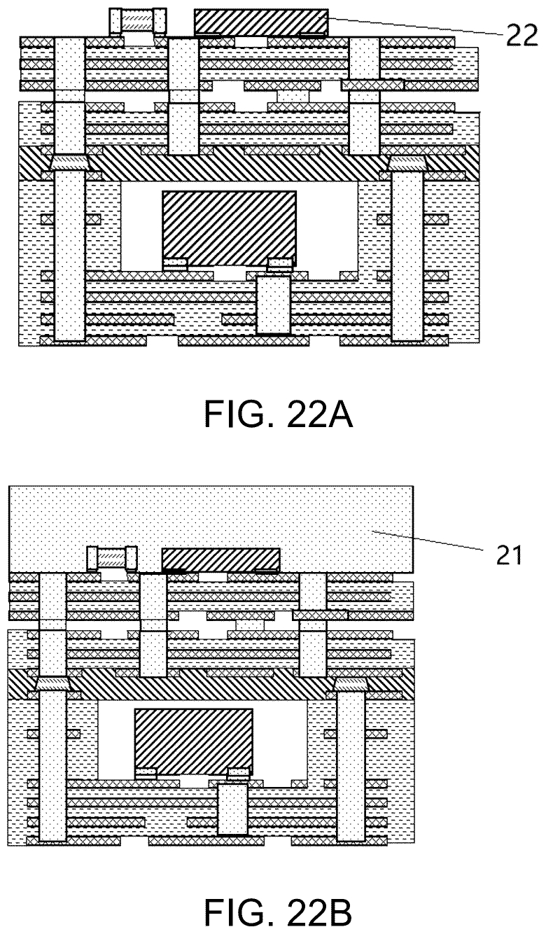

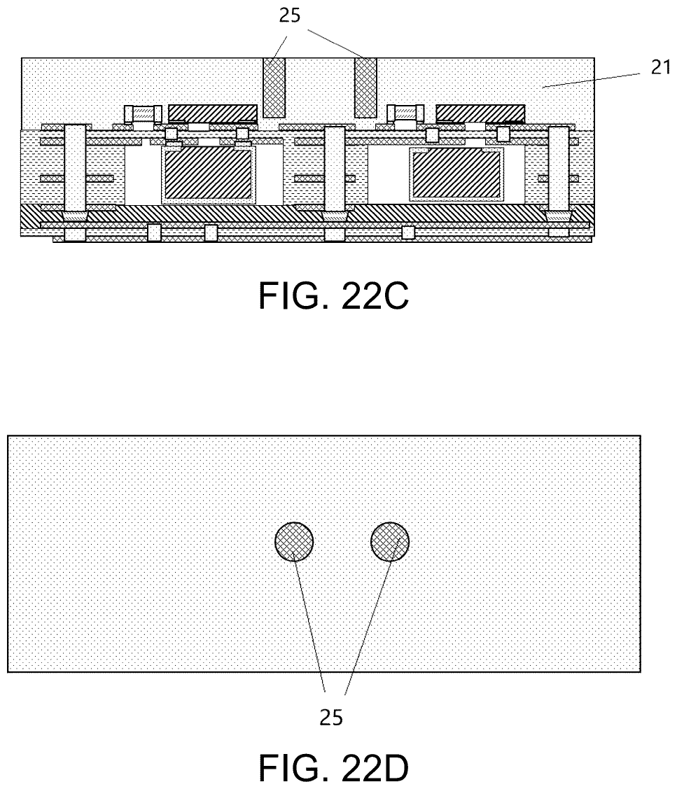

In a preferred embodiment, another substrate can be carried on the surface of the carrier plate 2, the circuit element 22 can be carried on the surface of the substrate, as shown in FIG. 22A, the circuit element 22 is connected in series with the winding of the transformer through the substrate to form a loop. In a preferred embodiment, a plastic package body 21 can also be formed on the surface of the substrate and the circuit element 22 to protect the circuit elements, as shown in FIG. 22B.

In a preferred embodiment, as shown in FIG. 22C and FIG. 22D (FIG. 22D is a top view), the carrier plate 2 is used for power conversion between the high-voltage side and the low-voltage side, the plastic package body 21 is arranged on the surface of the carrier plate 2 corresponding to the high-voltage side, a conductive conductor 25, such as a copper column, a stud, a nut, a metalized via hole or a solder ball, can be arranged in the plastic package body 21, and the plastic package body 21 and can be fan-out to the surface of the plastic package body 21. And the conductive conductor 25 is electrically connected with the outside through an insulated conductor, and the connection point exposed to the surface of the insulating dielectric can be located near the axis of the module, so that the creepage distance can be increased.

### Embodiment 14

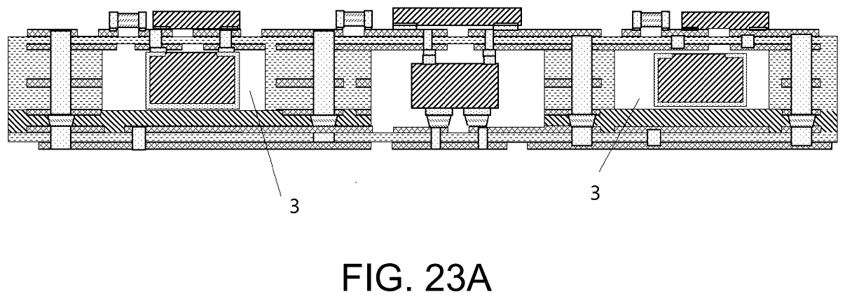

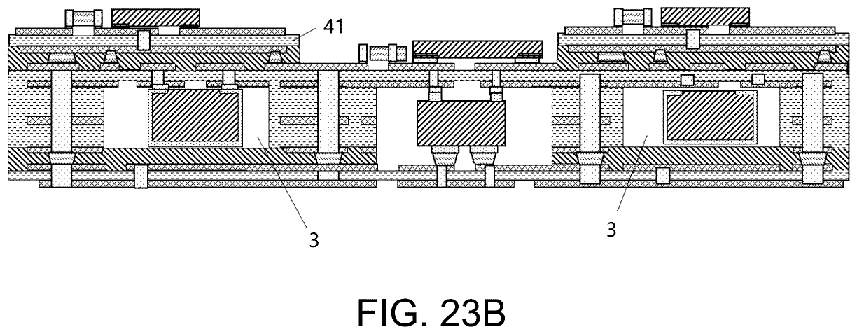

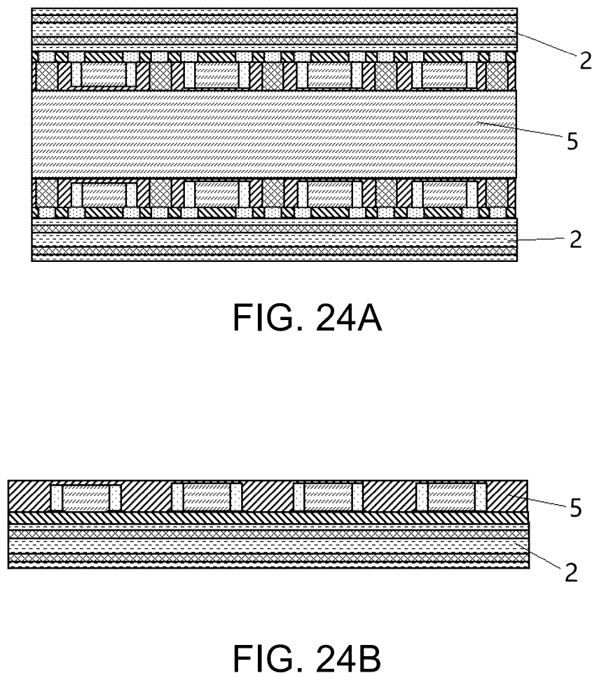

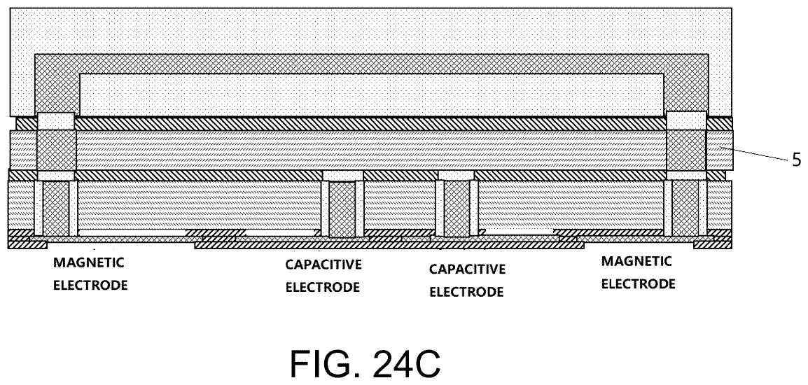

The power supply module of the embodiment is a two-stage voltage reduction module. As shown in FIG. 23A, the carrier plate 2 used by the two-stage voltage reduction module can be divided into a front-stage element area and a rear-stage element area, the front-stage element area is arranged on the periphery of the carrier plate 2, the rear-stage element area is arranged in the middle of the carrier plate 2, interconnection can be effectively simplified, and the front/rear-stage element areas respectively comprise respective hollowed-out areas and corresponding front/rear-stage power supply circuit assemblies. In the embodiment, the left hollowed-out area 3 and the right hollowed-out area 3 of FIG. 23A are annular communicated hollowed-out areas 3, the magnetic core 1 is an annular magnetic core, and the structure of the magnetic core 1 can be referred to the embodiment.

In a preferred embodiment, as shown in FIG. 23B, the front/rear element regions may have different lamination configurations, for example, the lamination layer 41 of the upper surface of the carrier plate on the surface layer is only provided in the front-stage element region, which makes the circuit elements of the front/rear-stage are arranged in staggered floor. A person skilled in the art can flexibly set the bonding material piece 7 and the bonding dielectric layer 6, the height and range of the hollowed-out area 3 can also be flexibly set, and the number and arrangement mode of the independent front/rear-stage element areas can also be flexibly set so as to meet the limitation of different wiring complexity, adaptive system different position heights and the like. Preferably, two or more carrier plates of the aforementioned embodiments can also be stacked for improving wiring flexibility.

In a preferred embodiment, the power module comprises at least two electronic units, and the electronic unit is a single electronic component or an integrated unit of a plurality of electronic components or a substrate containing a multi-layer of wirings. The at least one electronic unit comprises at least one semiconductor device or a capacitor or a magnetic device, which is referred to as a first electronic unit and is equivalent to the electronic assembly 5 in each structure; and the other corresponding one is a second electronic unit. At least one surface of each of the at least two electronic units is provided with a plurality of mutually-flat exposed electrodes, and the electrodes of the two electronic units correspond to each other. A bonding dielectric layer corresponding to an electrode windowing is placed on the surface of the electrode containing one electronic unit, then sintering slurry is arranged at the windowing position and then is pressed into a whole with the other electronic unit, internal high-quality high-temperature-resistant electrical interconnection is achieved while the structure is fixed, and a pre-finished product in the production process of the high-temperature-resistant electronic module or the electronic module is formed.

In FIG. 24A and FIG. 24B, the first electronic unit is an integrated body integrated with multiple electronic components through a plastic packaging process. In FIG. 24A, the plastic package integration body is a plastic package after a plurality of small-size electronic element horizontal arrays and at least one large element are vertically stacked. In FIG. 24B, the plastic package integration body is a plastic package after a plurality of electronic elements are horizontally arrayed. In order to guarantee flatness, a plurality of electronic components of the horizontal array in FIG. 24A and FIG. 24B are subjected to plastic packaging after leveling through a carrier, the electrodes are exposed and cleaned after plastic packaging, and when necessary, electroplating is performed on the surface of the plastic package body, so that the surface electrode of the plastic package first electronic unit has more effective sintering interconnection conditions. In FIG. 24C, the first electronic unit is a flat multi-electrode device.

In FIG. 24A, a power supply module is a common circuit such as a Buck circuit, a Boost circuit, a power semiconductor element needing to be stacked and integrated, a power semiconductor loop suppression capacitor (an input capacitor of Buck circuit and an output capacitor of Boost circuit), the magnetic element even comprises a filter capacitor (an output capacitor of Buck circuit, an input capacitor of Boost circuit) matched with the magnetic element and a module pin, so that the structure scheme with the minimum occupied area is realized. In the manufacturing process of the structural body, the plurality of capacitors are subjected to plastic package fixing by taking the magnetic element as a structural carrier, and the sintered slurry and the windowing/bonding dielectric layer are used for interconnection with the PCB substrate after the electrode is led out as shown in FIG. 24B. In some more complex high-density and high-reliability power supplies, a plurality of components are usually integrated together by using a full-plastic packaging process.

However, the electrical connection of each element in the traditional process is carried out through tin material welding, and when a user is used for welding, soldering tin in the module is remelted, so that the structure is unstable or even short-circuit failure caused by tin soldering is caused. Firstly, the electronic components are molded and then led out of the electrode to the surface, and then the sintered slurry and the windowing bonding dielectric layer are interconnected with the PCB substrate.

Therefore, the second electronic unit in FIG. 24A/B is a PCB substrate, a power semiconductor can be placed in the substrate or on the other side, and high-density, low-internal-resistance, low-internal thermal resistance and complex electric functions are achieved.

FIG. 24C is used in an ultra-thin type such as a 1 mm height scene. The first electronic unit is a flat passive device, the second unit is a semiconductor chip, one surface of the semiconductor chip is provided with a plurality of electrodes, and the surface is electrically and structurally interconnected with the passive devices of the multiple electrodes through the windowing/bonding dielectric layer.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A carrier plate, comprising at least two prefabricated printed circuit board lamination layers, wherein the at least one printed circuit board lamination layer is provided with a first surface, at least one hollowed-out area is formed in the first surface, the hollowed-out area is embedded in the carrier plate, the printed circuit board lamination layer is fixedly connected through an insulating bonding dielectric layer, an electrical connector penetrating through the bonding dielectric layer is arranged in the carrier plate, and at least one power supply circuit assembly is arranged in the hollowed-out area.

2. The carrier plate of claim 1, wherein the power supply circuit assembly comprises at least one magnetic core, the printed circuit board lamination layer comprises at least one part of windings, and the winding and the magnetic core are configured for forming magnetic elements in the power supply circuit assembly through mutual cooperation.

3. The carrier plate of claim 2, wherein at least one hollow area is provided with a side wall metal piece, the at least one side wall metal piece is configured for forming at least a part of windings, and the winding and the magnetic core are configured for forming magnetic elements in the power supply circuit assembly through mutual cooperation.

4. The carrier plate of claim 2, wherein an outer side metal part is arranged on the side wall of an outer edge of the printed circuit board lamination layer where the side wall metal piece is located, and the outer side metal part is configured for forming the at least one part of windings.

5. The carrier plate of claim 1, wherein the electrical connector penetrating through the bonding dielectric layer comprises a bonding material piece, and the bonding material piece is made of a non-remelting conductive bonding material; and the non-remelting conductive bonding material does not remelting in 220° C.

6. The carrier plate of claim 1, wherein the power supply circuit assembly and the printed circuit board lamination layer are electrically connected through one or more conductive connecting pieces, and the conductive connecting piece is made of a non-remelting conductive bonding material; and the non-remelting conductive bonding material does not remelting in 220° C.

7. The carrier plate of claim 5, wherein the non-remelting conductive bonding material comprises at least one of brazing filler metal, tin-silver alloy, tin-copper alloy, tin-silver-copper alloy, tin-antimony alloy, gold-tin alloy, high-lead solder, silver sintering slurry, copper sintering slurry, instantaneous liquid-phase sintering material or conductive slurry.

8. The carrier plate of claim 1, wherein the electrical connector penetrating through the bonding dielectric layer comprises a via hole electroplating piece.

9. The carrier plate of claim 1, wherein a material of the bonding dielectric layer comprises at least one of a prepreg or ABF.

10. The carrier plate of claim 1, wherein an insulating filler is provided in the hollow area, and the insulating filler covers the power supply circuit assembly.

11. The carrier plate of claim 1, wherein the hollow structure comprises at least one step area, and power supply circuit assemblies with different heights are arranged in the step area and the step area respectively.

12. The carrier plate of claim 1, wherein at least one printed circuit board lamination layer is provided with a second surface, the second surface is not provided with a hollowed-out area, a power supply circuit assembly is arranged on the second surface, and the power supply circuit assembly on the second surface is located in a hollowed-out area formed in the other printed circuit board lamination layer.

13. The carrier plate of claim 1, wherein at least two adjacent printed circuit board lamination layers are provided with hollowed-out areas, and the corresponding hollowed-out areas are communicated.

14. The carrier plate of claim 1, wherein at least three printed circuit board lamination layers are arranged; and at least one printed circuit board lamination layer is penetrated by a hollowed-out area.

15. The carrier plate of claim 1, wherein at least three printed circuit board lamination layers are arranged; at least two hollowed-out areas are arranged; and the hollowed-out areas are respectively arranged on different printed circuit board lamination layer and/or on different surfaces of the printed circuit board lamination layer.

16. The carrier plate of claim 1, wherein the magnetic core spans the at least one printed circuit board lamination layer, the plurality of hollow areas are provided, and the plurality of hollow areas are respectively configured for accommodating a part of the magnetic core.

17. The carrier plate of claim 1, wherein at least one power supply circuit assembly is electrically connected with two different printed circuit board lamination layers through pins.

18. The carrier plate of claim 17, wherein the printed circuit board lamination layer corresponding to the at least one pin is provided with an electrical connection semi-counterbore.

19. The carrier plate of claim 17, wherein at least one of the pins is an elastic pin.

20. The carrier plate of claim 1, wherein at least one hollow area is provided with a side wall metal piece, and the at least one side wall metal piece is configured for forming a signal shielding layer.

21. The carrier plate of claim 3, wherein a plurality of side wall metal pieces are arranged on one side wall of the same hollow area, and the side wall metal pieces extend in a thickness direction of the carrier plate and are arranged in an array in the horizontal direction.

22. The carrier plate of claim 3, wherein the side wall metal member is provided with solder at a top or a bottom of the hollow region, or the side wall metal member and the printed circuit board lamination layer are electrically connected by a flying wire.

23. A high-integration transformer unit, comprising an annular magnetic core, a primary winding, a secondary winding and a carrier plate, wherein the carrier comprises at least two prefabricated printed circuit board lamination layer; an annular hollow area configured for accommodating the annular magnetic core is formed in the at least one printed circuit board lamination layer, the printed circuit board lamination layer wraps the annular magnetic core through buckling, and the printed circuit board lamination layer is fixedly connected through a bonding dielectric layer; and at least one part of the primary side winding and the secondary side winding is arranged in the printed circuit board lamination layer.

24. The transformer unit of claim 23, wherein one of the primary winding or the secondary winding is arranged on a surface of the annular magnetic core, and a lamination layer of the primary winding or the secondary winding is electrically connected with the printed circuit board lamination layer through at least two conductive connecting pieces.

25. The transformer unit of claim 24, wherein an insulating transition layer is further arranged between one of the primary winding or the secondary winding and the surface of the annular magnetic core.

26. The transformer unit of claim 24, wherein an insulation protection layer is further arranged on an outer side of one of the primary winding or the secondary winding.

27. The transformer unit of claim 24, wherein the other one of the primary winding or the secondary winding is arranged on the printed circuit board lamination layer and comprises a first winding and a second winding which are nested inside and outside.

28. The transformer unit of claim 27, wherein a plurality of side wall metal pieces are arranged in the annular hollowed-out area, the side wall metal pieces extend in a thickness direction of the carrier plate and are arranged in an array in a horizontal direction, and the side wall metal pieces are configured for forming vertical parts of the first winding.

29. The transformer unit of claim 27, wherein a plurality of outer side metal pieces are arranged on a side wall of an outer edge of the printed circuit board lamination layer, and the outer side metal pieces are configured for forming vertical parts of the second winding.

30. The transformer unit of claim 24, wherein the at least two conductive connectors are respectively electrically connected to different printed circuit board lamination layer.

31. The transformer unit of claim 23, wherein the primary winding and/or the secondary winding comprise at least three windings nested inside and outside.

32. The transformer unit of claim 23, wherein a vertical via hole is formed in the carrier plate, a bonding material piece is arranged at a position, corresponding to the vertical via hole, of the bonding dielectric layer, and the vertical via hole and the bonding material piece are configured for forming a vertical section of the primary winding and/or a vertical section of the secondary winding.

33. The transformer unit of claim 23, wherein a vertical via hole is provided in the carrier plate, the vertical via hole penetrates the bonding dielectric layer, and the vertical via hole is configured for forming a vertical section of the primary winding and/or a vertical section of the secondary winding.

34. The transformer unit of claim 33, wherein at least one vertical via hole arranged in the middle of the annular magnetic core is a vertical section shared by a plurality of primary windings or a vertical section shared by a plurality of secondary windings.

35. The transformer unit of claim 23, further comprising a circuit element, wherein the circuit element comprises a switching element and/or a driving element and/or a capacitive element and/or a controller; and the switching element comprises a primary side switching element and/or a secondary side switching element, the primary side winding switching element and the primary side winding are connected in series, and the secondary side winding switching element and the secondary side winding are connected in series.

36. The transformer unit of claim 35, wherein the carrier plate is provided with a heat dissipation surface; the circuit element is arranged on the heat dissipation surface, and/or the circuit element is arranged in the hollow area and is arranged on one surface adjacent to the heat dissipation surface.

37. The transformer unit of claim 35, wherein the switch elements are arranged on two opposite surfaces of the printed circuit board lamination layer in parallel and correspond to each other in position, one of the switch elements arranged in parallel is located in the hollow area, and the other one of the switch elements is located on an outer surface of the carrier plate.

38. The transformer unit of claim 35, further comprising a plastic package body, wherein the circuit element is arranged on an outer surface of the carrier plate, and the plastic package body wraps the circuit element and the outer surface.

39. The transformer unit of claim 38, wherein a conductive adapter is arranged in the plastic package body, one end of the conductive adapter is electrically connected with the carrier plate, and the other end of the conductive adapter is exposed out of a surface of the plastic package body; and the conductive adapter is arranged at the position adjacent to the central axis of the transformer unit.

40. A power supply device, comprising a two-stage architecture carrier plate, a front-stage magnetic core, a front-stage winding, a front-stage circuit element and a rear-stage circuit element, wherein the two-stage architecture carrier plate comprises at least two printed circuit board lamination layers, the two-stage architecture carrier plate is divided into a front-stage element area and a rear-stage element area according to circuit functions, and the front-stage element area is an annular area surrounding the rear-stage element area;
at least one printed circuit board lamination layer is provided with an annular hollowed-out area in the front-stage element area, the front-stage magnetic core is annular, and the front-stage magnetic core is arranged in the annular hollowed-out area;
the front-stage winding is arranged in the front-stage element area, and at least one part of the front-stage winding is arranged in the printed circuit board lamination layer;
the at least one printed circuit board lamination layer is provided with a middle hollowed-out area in the rear-stage element area, and at least one part of the rear-stage circuit element is arranged in the middle hollowed-out area;
the printed circuit board lamination layer is fixedly connected by a bonding dielectric layer, and an electrical connector penetrating through the bonding dielectric layer is provided in the two-stage architecture carrier.

41. The power supply device of claim 40, wherein an area of the front-stage element area is smaller than that of the rear-stage element area.

42. The power supply device of claim 40, wherein at least a part of the front-stage circuit element is arranged on an outer surface of the two-stage architecture carrier plate, and/or at least a part of the post-stage circuit element is arranged on the outer surface of the two-stage architecture carrier plate.

43. The power supply device of claim 40, wherein the two-stage architecture carrier plate has a first surface; in the front-stage element area or the rear-stage element area of the first surface, the printed circuit board lamination layer at an outermost layer is hollowed out, so that the printed circuit board lamination layer of the secondary outer layer is exposed; and at least a part of the front-stage circuit element and at least a part of the rear-stage circuit element are arranged in a staggered mode on the first surface.

44. The power supply device of claim 40, wherein the rear-stage circuit element comprises a rear-stage magnetic core, and the rear-stage magnetic core is arranged in the middle hollowed-out area.

45. A composite electronic component group, comprising at least two flat element groups, wherein the at least two flat element groups are fixedly connected through a bonding dielectric layer, bonding material parts are arranged in the bonding dielectric layers, and the flat element groups are electrically connected through bonding material parts;
the flat element group comprises at least one passive multi-electrode device, and the flat element group is able to be at least one of a PCB substrate or a semiconductor chip.

46. The composite electronic component group of claim 45, wherein the passive multi-electrode device comprises a capacitor element and a plastic package body which are horizontally arranged in an array mode, the plastic package body wraps the capacitor element, and an electrode of the capacitor element is exposed out of a surface of the plastic package body.

47. The composite electronic component group of claim 45, wherein the passive multi-electrode device comprises a capacitor element, a magnetic element and a plastic package body which are arranged in a horizontal array, the capacitor element is arranged on an upper surface and/or a lower surface of the magnetic element, the plastic package body wraps the capacitor element, and electrodes of the capacitor element and the magnetic element are respectively exposed out of a surface of the passive multi-electrode device.

48. The composite electronic component group of claim 45, wherein the passive multi-electrode device is a flat passive multi-electrode device, and the flat passive multi-electrode device is a layered capacitor, a flat magnetic element or a lamination combination of a layered capacitor and a flat magnetic element.

49. A power supply module, comprising the transformer unit of claim 23, and further comprising a substrate and a circuit unit, wherein the transformer unit and the circuit unit are respectively arranged on two opposite sides of the substrate; and the circuit unit is electrically connected to a winding of the transformer by the substrate.
